(19) United States
(12) Patent Application Publication
(10) Pub. No.: US 2024/0182614 A1
(43) Pub. Date: Jun. 6, 2024

(54) RESIN COMPOSITION, PREPREG, RESIN-COATED FILM, RESIN-COATED METAL FOIL, METAL-CLAD LAMINATE, AND WIRING BOARD

(71) Applicant: PANASONIC INTELLECTUAL PROPERTY MANAGEMENT CO., LTD., Osaka (JP)

(72) Inventors: Masashi KODA, Fukushima (JP); Akira IRIFUNE, Fukushima (JP); Mitsuyoshi NISHINO, Fukushima (JP); Hisashi FUJINAGA, Fukushima (JP); Yuuki HIROKAWA, Fukushima (JP)

(73) Assignee: PANASONIC INTELLECTUAL PROPERTY MANAGEMENT CO., LTD., Osaka (JP)

(21) Appl. No.: 18/282,942

(22) PCT Filed: Mar. 22, 2022
(86) PCT No.: PCT/JP2022/012960

§ 371 Date: Sep. 19, 2023

(30) Foreign Application Priority Data
Mar. 24, 2021 (JP) 2021-050476

(51) Int. Cl. C08F 212/34; C08J 5/24; C08K 3/013; C08K 3/22; C08K 3/36; C08K 9/02; C08K 9/06; H05K 1/03

(52) U.S. Cl. CPC C08F 212/34; C08J 5/244; C08K 3/013; C08K 9/02; C08K 9/06; H05K 1/0373; C08K 2003/222; C08K 3/36; H05K 2201/0104; H05K 2201/0166; H05K 2201/0215

(57) ABSTRACT

A resin composition contains a polyfunctional vinyl aromatic copolymer (A) containing a repeating unit (a) derived from a divinyl aromatic compound and a repeating unit (b) derived from a monovinyl aromatic compound, a curing agent (B), at least one filler (C) selected from the group consisting of a titanate compound filler (C1) and a magnesium oxide filler (C2), and a silica filler (D), in which the content ratio of the high dielectric constant filler (C) to the silica filler (D) is 10:90 to 90:10 as a mass ratio.

### TECHNICAL FIELD

The present invention relates to a resin composition, a prepreg, a film with resin, a metal foil with resin, a metal-clad laminate, and a wiring board.

### BACKGROUND ART

Wiring boards used in electronic devices are required to be compatible with high frequencies when used as, for example, wiring boards for antennas. Substrate materials for forming insulating layers included in such wiring boards compatible with high frequencies are required to have a low dielectric loss tangent in order to decrease the signal transmission loss. The substrate materials are also required to have a high relative dielectric constant in order to miniaturize the wiring boards.

Insulating layers included in wiring boards are manufactured using prepregs in which fibrous base materials such as glass cloth are impregnated with resin compositions in some cases. In such prepregs, in a case where the difference between the relative dielectric constant of the fibrous base materials and the relative dielectric constant of cured products of the resin compositions is large, the relative dielectric constant of cured products of the prepregs varies depending on the amount of the resin compositions blended into the fibrous base materials. In such cases, metal-clad laminates and wiring boards obtained using prepregs with glass cloth, the relative dielectric constant of insulating layers varies depending on the thickness and the like of these in a case where the amount of the resin compositions blended is different. Hence, when the obtained metal-clad laminates and wiring boards are manufactured using the same resin composition as well, the relative dielectric constant of insulating layers may vary and this may affect the substrate design such as wiring width. It is known that this effect is remarkable particularly in multilayer wiring boards and the like. For this reason, it is necessary to take the different relative dielectric constants of insulating layers into account in the substrate design.

It is known that distortion called skew that decreases signal quality occurs in wiring boards obtained using prepregs with glass cloth. It is known that deterioration in signal quality due to skew is more remarkable particularly in wiring boards equipped in electronic devices that utilize high frequency bands. It is considered that this is due to the generation of a difference in relative dielectric constant between the portion where the yarns constituting the glass cloth are present and the portion where the yarns are not present in metal-clad laminates and wiring boards obtained using prepregs with glass cloth.

For these reasons, there is a demand for resin compositions, which afford cured products having a relative dielectric constant close to a relative dielectric constant of the fibrous base materials in prepregs in which fibrous base materials such as glass cloth are impregnated with resin compositions. In a case where the relative dielectric constant of cured products of the resin compositions is lower than the relative dielectric constant of the fibrous base materials, the relative dielectric constant of cured products of the resin compositions is required to be high so as to approach the relative dielectric constant of the fibrous base materials. In order to deal with this point as well, there is a demand for resin compositions, which afford cured products having a high relative dielectric constant. As described above, the resin compositions are also required to afford cured products having a low dielectric loss tangent in order to decrease signal transmission loss in wiring boards. Substrate materials for forming insulating layers of wiring boards are also required not only to have a high relative dielectric constant and a low dielectric loss tangent but also to exhibit enhanced curability so as to afford cured products exhibiting excellent heat resistance and the like. This high heat resistance is particularly required in multilayer wiring boards and the like.

Examples of the resin compositions used for manufacturing insulating layers included in wiring boards include the resin composition described in Patent Literature 1. Patent Literature 1 describes a thermosetting resin composition containing a predetermined polyfunctional vinyl aromatic copolymer, a predetermined polybutadiene resin, and a filler. In Patent Literature 1, strontium titanate, barium titanate, and the like are mentioned as the filler.

It is considered that the relative dielectric constant can be increased by containing a filler having a high relative dielectric constant, for example, strontium titanate and barium titanate described in Patent Literature 1. However, by containing a filler having a high relative dielectric constant, the dielectric loss tangent may also increase and the heat resistance and the like may decrease even though the relative dielectric constant can be increased.

### CITATION LIST

### Patent Literature

Patent Literature 1: JP 2020-516742 A

### SUMMARY OF INVENTION

The present invention has been made in view of such circumstances, and an object thereof is to provide a resin composition, which affords a cured product having a high relative dielectric constant, a low dielectric loss tangent, and excellent heat resistance. Another object of the present invention is to provide a prepreg, a film with resin, a metal foil with resin, a metal-clad laminate, and a wiring board, which are obtained using the resin composition.

An aspect of the present invention is a resin composition containing a polyfunctional vinyl aromatic copolymer (A) containing a repeating unit (a) derived from a divinyl aromatic compound and a repeating unit (b) derived from a monovinyl aromatic compound, a curing agent (B), at least one high dielectric constant filler (C) selected from the group consisting of a titanate compound filler (C1) and a magnesium oxide filler (C2), and a silica filler (D), in which the content ratio of the high dielectric constant filler (C) to the silica filler (D) is 10:90 to 90:10 as a mass ratio.

### BRIEF DESCRIPTION OF DRAWINGS

FIG. 1 is a schematic sectional view illustrating an example of a prepreg according to an embodiment of the present invention.

FIG. 2 is a schematic sectional view illustrating an example of a metal-clad laminate according to an embodiment of the present invention.

FIG. 3 is a schematic sectional view illustrating an example of a wiring board according to an embodiment of the present invention.

FIG. 4 is a schematic sectional view illustrating another example of a wiring board according to an embodiment of the present invention.

FIG. 5 is a schematic sectional view illustrating an example of a metal foil with resin according to an embodiment of the present invention.

FIG. 6 is a schematic sectional view illustrating an example of a film with resin according to an embodiment of the present invention.

### DESCRIPTION OF EMBODIMENTS

In order to increase the relative dielectric constant of a cured product of a resin composition, it is conceivable to contain a filler having a high relative dielectric constant as described above. In order to further increase the relative dielectric constant of a cured product of a resin composition, it is also conceivable to increase the content of a filler having a high relative dielectric constant in the resin composition. However, according to the studies of the present inventors, by simply containing a filler having a high relative dielectric constant, as described above, the heat resistance may decrease, the dielectric loss tangent may also increase, and the like even though the relative dielectric constant can be increased depending on the composition of the resin component and filler contained in the resin composition, and the like. In such a case, when the content of a filler having a high relative dielectric constant in the resin composition is simply increased in order to further increase the relative dielectric constant, it is considered that the heat resistance further decreases or the dielectric loss tangent increases even though the relative dielectric constant can be further increased. As a result of extensive studies, the present inventors have found out that not only the resin component contained in a resin composition but also the kind, composition, and the like of the filler affect dielectric properties such as relative dielectric constant and dielectric loss tangent of a cured product and also affect the heat resistance of a cured product. It has been found out that the objects are achieved by the present invention described below as a result of further studies on this effect.

The present inventors have found out that the objects are achieved by the present invention described below as a result of extensive studies.

Hereinafter, embodiments according to the present invention will be described, but the present invention is not limited thereto.

### [Resin Composition]

A resin composition according to an embodiment of the present invention is a resin composition containing a polyfunctional vinyl aromatic copolymer (A) containing a repeating unit (a) derived from a divinyl aromatic compound and a repeating unit (b) derived from a monovinyl aromatic compound, a curing agent (B), at least one high dielectric constant filler (C) selected from the group consisting of a titanate compound filler (C1) and a magnesium oxide filler (C2), and a silica filler (D), in which the content ratio of the high dielectric constant filler (C) to the silica filler (D) is 10:90 to 90:10 as a mass ratio. By curing the resin composition having such a configuration, a cured product having a high relative dielectric constant, a low dielectric loss tangent, and excellent heat resistance is obtained.

By curing the polyfunctional vinyl aromatic copolymer (A) and curing agent (B) contained in the resin composition together, it is considered that the polyfunctional vinyl aromatic copolymer (A) is suitably cured and a cured product exhibiting excellent heat resistance is obtained. Since the resin composition contains the polyfunctional vinyl aromatic copolymer (A), it is considered that a cured product having a low dielectric loss tangent is obtained by curing the polyfunctional vinyl aromatic copolymer (A). This cured product is considered to have a low dielectric loss tangent as well as a low relative dielectric constant, and it is considered that the relative dielectric constant of the cured product can be increased by containing the high dielectric constant filler (C) in the resin composition. By containing the silica filler (D) as well as the high dielectric constant filler (C) in the resin composition and adjusting the content ratio thereof to the above ratio, it is considered that it is possible to increase the relative dielectric constant and heat resistance while suppressing an increase in dielectric loss tangent of the cured product. From these facts, it is considered that a cured product having a high relative dielectric constant, a low dielectric loss tangent, and excellent heat resistance is obtained.

In a prepreg obtained by impregnating a fibrous base material with a resin composition, when the difference between the relative dielectric constant of a cured product of the resin composition and the relative dielectric constant of the fibrous base material is large, the relative dielectric constant of a cured product of the prepreg varies depending on the amount of the resin composition blended into the fibrous base material. In this case, for example, the amount of the resin composition blended varies depending on the thickness and the like of the prepreg, and the relative dielectric constant of a cured product of the obtained prepreg varies. In contrast, since the resin composition according to the present embodiment has a high relative dielectric constant as described above, the difference in relative dielectric constant between the resin composition and the fibrous base material can be diminished. In this case, the difference in relative dielectric constant between cured products of the respective prepregs due to the different amounts of resin composition blended in the prepregs decreases. Hence, even though there is a difference in the thickness and the like of an insulating layer included in the wiring board, the difference in relative dielectric constant is small. Since a cured product of the resin composition has a high relative dielectric constant as described above, the difference between this relative dielectric constant and the relative dielectric constant of the fibrous base material included in the prepreg is small, and as the occurrence of skew in the finally obtained wiring board can also be suppressed.

As thinning of wiring boards proceeds, there is a tendency that warping of semiconductor packages in which semiconductor chips are mounted on wiring boards occurs and mounting failures are likely to occur. In order to suppress warping of semiconductor packages in which semiconductor chips are mounted on wiring boards, the insulating layers are required to have a low coefficient of thermal expansion. Hence, substrate materials for forming insulating layers of wiring boards are required to afford cured products having a low coefficient of thermal expansion. For this reason, substrate materials for wiring boards and the like are required to have a high relative dielectric constant, a low dielectric loss tangent and excellent heat resistance, as described above, and are further required to have a low coefficient of thermal expansion. In regard to this point, the resin composition according to the present embodiment affords a cured product having not only a high relative dielectric constant and a low dielectric loss tangent but also excellent heat resistance and a low coefficient of thermal expansion.

### (Polyfunctional Vinyl Aromatic Copolymer (A))

The polyfunctional vinyl aromatic copolymer (A) is not particularly limited as long as it is a polyfunctional vinyl aromatic copolymer containing a repeating unit (a) derived from a divinyl aromatic compound and a repeating unit (b) derived from a monovinyl aromatic compound. Examples of the polyfunctional vinyl aromatic copolymer (A) include a soluble polyfunctional vinyl aromatic copolymer, which is a polyfunctional vinyl aromatic copolymer containing the repeating unit (a) and the repeating unit (b), and in which the repeating unit (a) is contained at 2 mol % or more and less than 95 mol % and the repeating unit (b) is contained at 5 mol % or more and less than 98 mol % when the sum of the repeating unit (a) and the repeating unit (b) is set to 100 mol %, a repeating unit (a1) having an unsaturated group represented by the following Formula (a1) is contained, the mole fraction of the repeating unit (a1) in the total sum of the repeating unit (a) and the repeating unit (b) satisfies the following Expression (1), the number average molecular weight of the soluble polyfunctional vinyl aromatic copolymer is 300 to 100,000, the molecular weight distribution represented by the ratio of the weight average molecular weight to the number average molecular weight is 100.0 or less, and the soluble polyfunctional vinyl aromatic copolymer is soluble in toluene, xylene, tetrahydrofuran, dichloroethane or chloroform. The soluble polyfunctional vinyl aromatic copolymer is also simply referred to as a copolymer.

0.02≤(a1)/[(a)+(b)]≤0.8 (1)

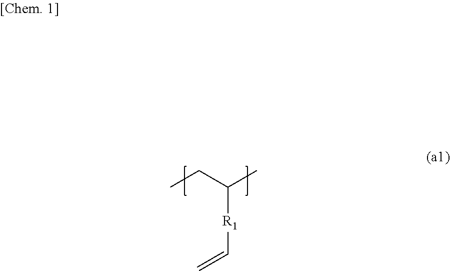

In the formula, R₁ represents an aromatic hydrocarbon group having 6 to 30 carbon atoms.

The soluble polyfunctional vinyl aromatic copolymer contains a repeating unit (a) derived from a divinyl aromatic compound and a repeating unit (b) derived from a monovinyl aromatic compound and further contains a repeating unit (at) represented by Formula (a1) as part of the repeating unit (a) derived from a divinyl aromatic compound.

In the soluble polyfunctional vinyl aromatic copolymer, the repeating unit (a) is contained at 2 mol % or more and less than 95 mol % and the repeating unit (b) is contained at 5 mol % or more and less than 98 mol % when the sum of the repeating unit (a) and the repeating unit (b) is set to 100 mol %. The repeating unit (a1) is contained at 2 to 80 mol % when the sum of the repeating unit (a) and the repeating unit (b) is set to 100 mol %.

The number average molecular weight Mn of the soluble polyfunctional vinyl aromatic copolymer is 300 to 100,000, the molecular weight distribution represented by the ratio (Mw/Mn) of the weight average molecular weight Mw to the number average molecular weight Mn is 100.0 or less, and the soluble polyfunctional vinyl aromatic copolymer is soluble in toluene, xylene, tetrahydrofuran, dichloroethane or chloroform.

The soluble polyfunctional vinyl aromatic copolymer is not particularly limited, but examples thereof include a copolymer containing structural units derived from a repeating unit (a) derived from a divinyl aromatic compound represented by the following Formulas (2) to (4) and a repeating unit (b) derived from a monovinyl aromatic compound. These structural units may be arranged regularly or randomly.

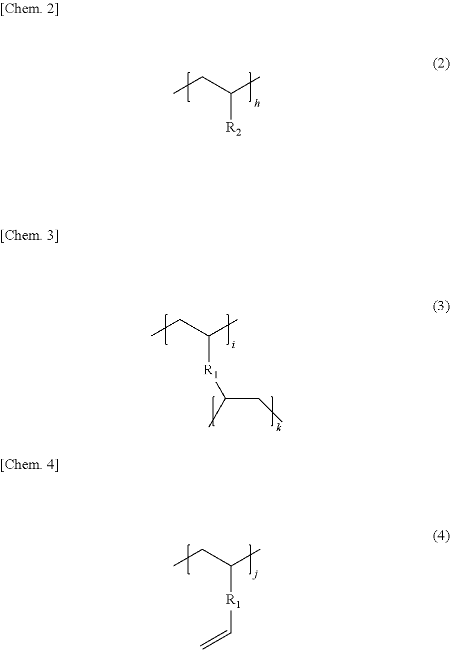

In the formula, R₁ is an aromatic hydrocarbon group having 6 to 30 carbon atoms derived from a divinyl aromatic compound, R₂ is an aromatic hydrocarbon group having 6 to 30 carbon atoms derived from a monovinyl aromatic compound, and h through k are each independently an integer 0 to 200, provided that the sum thereof is 2 to 20,000.

Suitable examples of the soluble polyfunctional vinyl aromatic copolymer include copolymers composed of repeating units in which R₁ and R₂ in Formulas (2) to (4) are aromatic hydrocarbon groups selected from the group consisting of a phenyl group optionally having a substituent, a biphenyl group optionally having a substituent, a naphthalene group optionally having a substituent, and a terphenyl group optionally having a substituent.

The soluble polyfunctional vinyl aromatic copolymer is solvent soluble. The repeating unit as used herein is derived from a monomer, and includes units that are present in the main chain of the copolymer and appear repeatedly and units or terminal groups that are present in the terminals or side chains. A repeating unit is also called a structural unit. The terminal group as used herein includes terminal groups derived from chain transfer agents described later in addition to those derived from the above monomers.

The structural unit (a) derived from a divinyl aromatic compound is contained at 2 mol % or more and less than 95 mol % with respect to the total sum of the structural unit (a) derived from a divinyl aromatic compound and the structural unit (b) derived from a monovinyl aromatic compound. The structural unit (a) derived from a divinyl aromatic compound can have a plurality of structures, such as one in which only one of two vinyl groups is reacted and one in which two of two vinyl groups are reacted. Among these, the structural unit (a) derived from a divinyl aromatic compound contains a repeating unit in which only one vinyl group represented by Formula (a1) is reacted at preferably 2 to 80 mol %, more preferably 5 to 70 mol %, still more preferably 10 to 60%, particularly preferably 15 to 50% with respect to the total sum. As the repeating unit in which only one vinyl group represented by Formula (a1) is reacted is contained at 2 to 80 mol % with respect to the total sum, the dielectric loss tangent is low, the toughness is high, the heat resistance excellent, and the compatibility with other resins is excellent. When a resin composition is prepared, the wet heat resistance, resistance to thermal oxidation deterioration, and moldability are excellent. When the repeating unit in which only one vinyl group represented by Formula (a1) is reacted is contained at less than 2 mol %, the heat resistance tends to decrease. When the repeating unit in which only one vinyl group represented by Formula (a1) is reacted is contained at more than 80 mol %, the interlayer peel strength of the laminate tends to decrease.

The soluble polyfunctional vinyl aromatic copolymer contains the structural unit (b) derived from a monovinyl aromatic compound at 5 mol % or more and less than 98 mol %, preferably 10 mol % or more and less than 90 mol %, more preferably 15 mol % or more and less than 85 mol % with respect to the total sum. When the structural unit (b) derived from a monovinyl aromatic compound is contained at less than 5 mol %, moldability tends to be insufficient. When the structural unit (b) derived from a monovinyl aromatic compound is contained at more than 98 mol %, the heat resistance of cured product tends to be insufficient.

The vinyl group present in Formula (a1) acts as a crosslinking component and contributes to exertion of heat resistance of the soluble polyfunctional vinyl aromatic copolymer. Meanwhile, the structural unit (b) derived from a monovinyl aromatic compound does not have a vinyl group since it is considered that polymerization usually proceeds through a 1,2-addition reaction of a vinyl group. In other words, the structural unit (b) derived from a monovinyl aromatic compound does not act as a crosslinking component but contributes to exertion of moldability.

Examples of the monovinyl aromatic compound preferably include styrene. As the monovinyl aromatic compound, a monovinyl aromatic compound other than styrene can be used together with styrene.

In this case, the content of the structural unit (b1) derived from styrene is preferably 99 to 20 mol %, more preferably 98 to 30 mol % when the total content of the structural unit (b1) derived from styrene and the structural unit (b2) derived from a monovinyl aromatic compound other than styrene is set to 100 mol %. It is preferable that the content of the structural unit (b1) derived from styrene is in the above range since both resistance to thermal oxidation deterioration and moldability are exhibited. In a case where the structural unit (b1) derived from styrene is more than 99 mol %, the heat resistance tends to decrease. In a case where the structural unit (b2) derived from a monovinyl aromatic compound other than styrene is more than 80 mol % (in a case where the structural unit (b1) derived from styrene is less than 20 mol %), moldability tends to decrease.

The number average molecular weight Mn (number average molecular weight Mn in terms of standard polystyrene measured using GPC) of the soluble polyfunctional vinyl aromatic copolymer is preferably 300 to 100,000, more preferably 400 to 50,000, still more preferably 500 to 10,000. When the number average molecular weight Mn of the soluble polyfunctional vinyl aromatic copolymer is less than 300, the amount of the monofunctional copolymer component contained in the soluble polyfunctional vinyl aromatic copolymer increases, and so the heat resistance of cured product tends to decrease. When the number average molecular weight Mn of the soluble polyfunctional vinyl aromatic copolymer is more than 100,000, gel is likely to be formed, the viscosity is high, and so moldability tends to decrease.

The value of the molecular weight distribution (Mw/Mn) of the soluble polyfunctional vinyl aromatic copolymer represented by the ratio of the weight average molecular weight Mw (weight average molecular weight Mw in terms of standard polystyrene measured using GPC) to the number average molecular weight Mn is 100.0 or less, preferably 50.0 or less, more preferably 1.5 to 30.0, still more preferably 2.0 to 20.0. When the Mw/Mn is more than 100.0, the processing characteristics of the soluble polyfunctional vinyl aromatic copolymer tend to deteriorate, and gel tends to be formed.

The soluble polyfunctional vinyl aromatic copolymer is soluble in toluene, xylene, tetrahydrofuran, dichloroethane or chloroform as a solvent, and is preferably soluble in any of the solvents. In order for the copolymer to be soluble in solvents and polyfunctional, it is necessary that some of the vinyl groups in divinylbenzene remain without being crosslinked to afford proper degree of crosslinking. Here, “soluble in a solvent” means that 5 g or more, more preferably 30 g or more, particularly preferably 50 g or more of the soluble polyfunctional vinyl aromatic copolymer is dissolved in 100 g of the solvent.

The divinyl aromatic compound plays a role in forming a branched structure and making the copolymer polyfunctional as well as plays a role as a crosslinking component for exerting heat resistance when the obtained soluble polyfunctional vinyl aromatic copolymer is heat-cured.

The divinyl aromatic compound is not particularly limited as long as it is an aromatic compound having two vinyl groups, but for example, divinylbenzene (including the respective regioisomers or mixtures thereof), divinylnaphthalene (including the respective regioisomers or mixtures thereof), and divinylbiphenyl (including the respective regioisomers or mixtures thereof) are preferably used. These can be used singly or in combination of two or more kinds thereof. Divinylbenzene (m-isomer, p-isomer, or a regioisomer mixture thereof) is more preferable from the viewpoint of moldability.

Examples of the monovinyl aromatic compound include styrene and monovinyl aromatic compounds other than styrene. As the monovinyl aromatic compound, it is desirable to use styrene essentially and a monovinyl aromatic compound other than styrene concurrently.

Styrene plays a role in imparting low dielectric properties and resistance to thermal oxidation deterioration to the soluble polyfunctional vinyl aromatic copolymer as a monomer component as well as plays a role in controlling the molecular weight of the soluble polyfunctional vinyl aromatic copolymer as a chain transfer agent. The monovinyl aromatic compound other than styrene improves the solubility in solvent and processability of the soluble polyfunctional vinyl aromatic copolymer.

The monovinyl aromatic compound other than styrene is not particularly limited as long as it is an aromatic compound having one vinyl group other than styrene, and examples thereof include vinyl aromatic compounds such as vinylnaphthalene and vinylbiphenyl; and nuclear alkyl-substituted vinyl aromatic compounds such as o-methylstyrene, m-methylstyrene, p-methylstyrene, o,p-dimethylstyrene, o-ethylvinylbenzene, m-ethylvinylbenzene and p-ethylvinylbenzene. The monovinyl aromatic compound other than styrene is preferably ethylvinylbenzene (including the respective regioisomers or mixtures thereof), ethylvinylbiphenyl (including the respective regioisomers or mixtures thereof), or ethylvinylnaphthalene (including the respective regioisomers and mixtures thereof) since the compound prevents gelation of the soluble polyfunctional vinyl aromatic copolymer, is highly effective in improving solubility in solvent and processability, is low in cost, and is readily available. The monovinyl aromatic compound other than styrene is preferably ethylvinylbenzene (m-isomer, p-isomer, or a regioisomer mixture of thereof) from the viewpoint of dielectric properties and cost.

In addition to the divinyl aromatic compound and the monovinyl aromatic compound, for example, structural units (c) derived from one or two or more other monomer components such as a trivinyl aromatic compound, a trivinyl aliphatic compound, a divinyl aliphatic compound, and a monovinyl aliphatic compound can be introduced into the soluble polyfunctional vinyl aromatic copolymer as long as the effects of the present invention are not impaired.

Examples of the other monomer components include 1,3,5-trivinylbenzene, 1,3,5-trivinylnaphthalene, 1,2,4-trivinylcyclohexane, ethylene glycol diacrylate, butadiene, 1,4-butanediol divinyl ether, cyclohexanedimethanol divinyl ether, diethylene glycol divinyl ether and triallyl isocyanurate. These can be used singly or in combination of two or more kinds thereof.

The mole fraction of the other monomer components is preferably less than 30 mol % with respect to the total sum of all monomer components. In other words, the mole fraction of the repeating unit (c) derived from other monomer components is preferably less than 30 mol % with respect to the structural units (the total sum of the structural unit (a), the structural unit (b), and the structural unit (c)) derived from all the monomer components constituting the soluble polyfunctional vinyl aromatic copolymer.

The soluble polyfunctional vinyl aromatic copolymer is obtained by polymerizing monomers including the divinyl aromatic compound and the monovinyl aromatic compound in the presence of a Lewis acid catalyst. A known chain transfer agent (CTR) may also be added during polymerization for the purpose of controlling the molecular weight.

### (Curing Agent (B))

The curing agent (B) is not particularly limited as long as it reacts with the polyfunctional vinyl aromatic copolymer (A) and contributes to curing of the resin composition. Examples of the curing agent (B) include an allyl compound, a methacrylate compound, an acrylate compound, an acenaphthylene compound, a vinyl compound, a maleimide compound, a polyphenylene ether compound, a cyanate ester compound, an active ester compound, and a benzoxazine compound.

The allyl compound is a compound having an allyl group in the molecule, and examples thereof include a triallyl isocyanurate compound such as triallyl isocyanurate (TAIC), a diallyl bisphenol compound, and diallyl phthalate (DAP).

The methacrylate compound is a compound having a methacryloyl group in the molecule, and examples thereof include a monofunctional methacrylate compound having one methacryloyl group in the molecule and a polyfunctional methacrylate compound having two or more methacryloyl groups in the molecule. Examples of the monofunctional methacrylate compound include methyl methacrylate, ethyl methacrylate, propyl methacrylate, and butyl methacrylate. Examples of the polyfunctional methacrylate compound include dimethacrylate compounds such as tricyclodecanedimethanol dimethacrylate (DCP).

The acrylate compound is a compound having an acryloyl group in the molecule, and examples thereof include a monofunctional acrylate compound having one acryloyl group in the molecule and a polyfunctional acrylate compound having two or more acryloyl groups in the molecule. Examples of the monofunctional acrylate compound include methyl acrylate, ethyl acrylate, propyl acrylate, and butyl acrylate. Examples of the polyfunctional acrylate compound include diacrylate compounds such as tricyclodecanedimethanol diacrylate.

The acenaphthylene compound is a compound having an acenaphthylene structure in the molecule. Examples of the acenaphthylene compound include acenaphthylene, alkylacenaphthylenes, halogenated acenaphthylenes, and phenylacenaphthylenes. Examples of the alkylacenaphthylenes include 1-methyl acenaphthylene, 3-methyl acenaphthylene, 4-methyl acenaphthylene, 5-methyl acenaphthylene, 1-ethyl acenaphthylene, 3-ethyl acenaphthylene, 4-ethyl acenaphthylene, and 5-ethyl acenaphthylene. Examples of the halogenated acenaphthylenes include 1-chloroacenaphthylene, 3-chloroacenaphthylene, 4-chloroacenaphthylene, 5-chloroacenaphthylene, 1-bromoacenaphthylene, 3-bromoacenaphthylene, 4-bromoacenaphthylene, and 5-bromoacenaphthylene. Examples of the phenylacenaphthylenes include 1-phenylacenaphthylene, 3-phenylacenaphthylene, 4-phenylacenaphthylene, and 5-phenylacenaphthylene. The acenaphthylene compound may be a monofunctional acenaphthylene compound having one acenaphthylene structure in the molecule as described above or may be a polyfunctional acenaphthylene compound having two or more acenaphthylene structures in the molecule.

The vinyl compound is a compound having a vinyl group in the molecule. Examples of the vinyl compound include a monofunctional vinyl compound (monovinyl compound) having one vinyl group in the molecule and a polyfunctional vinyl compound having two or more vinyl groups in the molecule. Examples of the polyfunctional vinyl compound include a polyfunctional aromatic vinyl compound and a vinyl hydrocarbon-based compound. Examples of the vinyl hydrocarbon-based compound include divinylbenzene and a polybutadiene compound.

The maleimide compound is a compound having a maleimide group in the molecule. Examples of the maleimide compound include a monofunctional maleimide compound having one maleimide group in the molecule, a polyfunctional maleimide compound having two or more maleimide groups in the molecule, and a modified maleimide compound. Examples of the modified maleimide compound include a modified maleimide compound in which a part of the molecule is modified with an amine compound, a modified maleimide compound in which a part of the molecule is modified with a silicone compound, and a modified maleimide compound in which a part of the molecule is modified with an amine compound and a silicone compound.

The polyphenylene ether compound is a compound having a polyphenylene ether chain in the molecule. Examples of the polyphenylene ether compound include a polyphenylene ether compound having an unsaturated double bond in the molecule. More specific examples of the polyphenylene ether compound include a polyphenylene ether compound having a vinylbenzyl group (ethenylbenzyl group) in the molecule (vinylbenzyl-modified polyphenylene ether), a polyphenylene ether compound having an acryloyl group in the molecule (acryl-modified polyphenylene ether), and a polyphenylene ether compound having a methacryloyl group in the molecule (methacryl-modified polyphenylene ether).

The cyanate ester compound is a compound having a cyanato group in the molecule, and examples thereof include 2,2-bis(4-cyanatophenyl)propane, bis(3,5-dimethyl-4-cyanatophenyl)methane, and 2,2-bis(4-cyanatophenyl)ethane.

The active ester compound is a compound having an ester group exhibiting high reaction activity in the molecule, and examples thereof include a benzenecarboxylic acid active ester, a benzenedicarboxylic acid active ester, a benzenetricarboxylic acid active ester, a benzenetetracarboxylic acid active ester, a naphthalenecarboxylic acid active ester, a naphthalenedicarboxylic acid active ester, a naphthalenetricarboxylic acid active ester, a naphthalenetetracarboxylic acid active ester, a fluorenecarboxylic acid active ester, a fluorenedicarboxylic acid active ester, a fluorenetricarboxylic acid active ester, and a fluorenetetracarboxylic acid active ester.

The benzoxazine compound is a compound having a benzoxazine ring in the molecule, and examples thereof include a benzoxazine resin.

As the curing agent (B), an allyl compound, a methacrylate compound, an acrylate compound, an acenaphthylene compound, a polybutadiene compound, a polyfunctional aromatic vinyl compound, a vinyl hydrocarbon-based compound, a maleimide compound, and a polyphenylene ether compound are preferable among these. The curing agent (B) may be used singly or in combination of two or more kinds thereof. In other words, the curing agent (B) preferably includes at least one selected from the group consisting of an allyl compound, a methacrylate compound, an acrylate compound, an acenaphthylene compound, a polybutadiene compound, a polyfunctional aromatic vinyl compound, a vinyl hydrocarbon-based compound, a maleimide compound, and a polyphenylene ether compound.

### (High Dielectric Constant Filler (C))

The high dielectric constant filler (C) is, as described above, at least one high dielectric constant filler selected from the group consisting of the titanate compound filler (C1) and the magnesium oxide filler (C2). In other words, the high dielectric constant filler (C) may be only the titanate compound filler (C1), only the magnesium oxide filler (C2), or a combination of these two.

The titanate compound filler (C1) is not particularly limited as long as it is a filler containing a titanate compound. Examples of the titanate compound filler include titanium oxide particles and metal titanate compound particles. Examples of the metal titanate compound particles include particles containing titanium and having a perovskite crystal structure or a composite perovskite crystal structure. Specific examples of the metal titanate compound particles include barium titanate particles, strontium titanate particles, calcium titanate particles, magnesium titanate particles, zinc titanate particles, lanthanum titanate particles, and neodymium titanate particles. Among these, the titanate compound filler (C1) is preferably the strontium titanate particles and the calcium titanate particles. The titanate compound filler (C1) may be used singly or in combination of two or more kinds thereof. In other words, the titanate compound filler (C1) preferably includes at least one selected from the group consisting of titanium oxide particles, barium titanate particles, strontium titanate particles, calcium titanate particles, magnesium titanate particles, zinc titanate particles, lanthanum titanate particles, and neodymium titanate particles, and more preferably includes at least one of the strontium titanate particles and the calcium titanate particles.

The magnesium oxide filler (C2) is not particularly limited as long as it contains magnesium oxide. Examples of the magnesium oxide filler (C2) include magnesium oxide. Examples of the magnesium oxide filler (C2) include a magnesium oxide filler obtained by oxidizing a metal magnesium filler through burning, a magnesium oxide filler obtained by thermally decomposing a magnesium hydroxide filler through calcination, and a magnesium oxide filler obtained by thermally decomposing a magnesium carbonate filler through calcination.

The high dielectric constant filler (C) may be a filler subjected to surface treatment or a filler not subjected to surface treatment, but is preferably a filler subjected to surface treatment. Examples of the surface treatment include treatment with coupling agents such as a silane coupling agent and a titanium coupling agent. In other words, the high dielectric constant filler (C) is preferably subjected to surface treatment with a silane coupling agent or a titanium coupling agent.

Examples of the silane coupling agent and titanium coupling agent include coupling agents having at least one functional group selected from the group consisting of a vinyl group, a styryl group, a methacryloyl group, an acryloyl group, a phenylamino group, an isocyanurate group, a ureido group, a mercapto group, an isocyanate group, an epoxy group, and an acid anhydride group. In other words, examples of the silane coupling agent and titanium coupling agent include compounds having at least one of a vinyl group, a styryl group, a methacryloyl group, an acryloyl group, a phenylamino group, an isocyanurate group, a ureido group, a mercapto group, an isocyanate group, an epoxy group, or an acid anhydride group as a reactive functional group, and further a hydrolyzable group such as a methoxy group or an ethoxy group.

Examples of the silane coupling agent include vinyltriethoxysilane and vinyltrimethoxysilane as those having a vinyl group. Examples of the silane coupling agent include p-styryltrimethoxysilanc and p-styryltriethoxysilane as those having a styryl group. Examples of the silane coupling agent include 3-methacryloxypropyltrimethoxysilane, 3-methacryloxypropylmethyldimethoxysilane, 3-methacryloxypropyltriethoxysilane, 3-methacryloxypropylmethyldiethoxysilane, and 3-methacryloxypropylethyldiethoxysilane as those having a methacryloyl group. Examples of the silane coupling agent include 3-acryloxypropyltrimethoxysilane and 3-acryloxypropyltriethoxysilane as those having an acryloyl group. Examples of the silane coupling agent include N-phenyl-3-aminopropyltrimethoxysilanc and N-phenyl-3-aminopropyltriethoxysilane as those having a phenylamino group. Examples of the titanium coupling agent include isopropyl (N-ethylaminoethylamino) titanate, isopropyl triisostearoyl titanate, titanium di(dioctylpyrophosphate)oxyacetate, tetraisopropyldi(dioctylphosphite)titanate, and neoalkoxytri(p-N-(β-aminoethyl)aminophenyl)titanate. These coupling agents may be used singly or in combination of two or more kinds thereof.

The relative dielectric constant of the high dielectric constant filler (C) is higher than the relative dielectric constant of the silica filler (D). By containing such a high dielectric constant filler (C) having a relative dielectric constant higher than the relative dielectric constant of the silica filler (D), a cured product having a high relative dielectric constant and a low dielectric loss tangent is suitably obtained. The relative dielectric constant of the titanate compound filler (C1) is preferably 50 or more, more preferably 70 to 800, still more preferably 90 to 700. By containing the titanate compound filler (C1) having such a relative dielectric constant, a cured product having a high relative dielectric constant and a low dielectric loss tangent is more suitably obtained.

The average particle size of the high dielectric constant filler (C) is not particularly limited. The average particle size of the high dielectric constant filler (C) also varies depending on the kind and the like of the high dielectric constant filler (C). In a case where the high dielectric constant filler (C) is the titanate compound filler (C1), the average particle size thereof is, for example, preferably 10 μm or less, more preferably 0.1 to 8 μm, still more preferably 0.3 to 5 μm. In a case where the high dielectric constant filler (C) is the magnesium oxide filler (C2), the average particle size thereof is, for example, preferably 0.1 μm or more, more preferably 0.1 to 15 μm, still more preferably 0.5 to 10 μm. When the high dielectric constant filler (C) has such a particle size, it is possible to further increase the relative dielectric constant while further suppressing an increase in the dielectric loss tangent of a cured product of the obtained resin composition. Here, the average particle size is the volume average particle size, and examples thereof include volume-based cumulative 50% diameter (D50). Specific examples thereof include the particle size (D50) where the cumulative particle size distribution from the small particle size side is 50% (based on volume) in the particle size distribution measured by a general laser diffraction/scattering method (volume-based cumulative 50% diameter in laser diffraction/scattering particle size distribution measurement).

The specific gravity of the high dielectric constant filler (C) is not particularly limited. The specific gravity of the high dielectric constant filler (C) also varies depending on the kind and the like of the high dielectric constant filler (C), but is preferably 3 to 7 g/cm³.

The specific surface area of the magnesium oxide filler (C2) is not particularly limited. The specific surface area of the high dielectric constant filler (C) is preferably 100 m²/g or less, more preferably 50 m²/g or less, still more preferably 0.1 to 20 m²/g. The specific surface area can be measured by a known method such as the BET specific surface area measurement method.

### (Silica Filler (D))

The silica filler (D) is not particularly limited, and examples thereof include silica fillers commonly used as fillers contained in resin compositions. The silica filler is not particularly limited, and examples thereof include crushed silica, spherical silica, and silica particles.

The silica filler (D) may be a filler subjected to surface treatment or a filler not subjected to surface treatment as the high dielectric constant filler (C). Examples of the surface treatment include treatment with coupling agents such as a silane coupling agent and a titanium coupling agent. The silane coupling agent and the titanium coupling agent are not particularly limited, but examples thereof include coupling agents similar to the silane coupling agent and titanium coupling agent used in the surface treatment of the high dielectric constant filler (C).

The average particle size of the silica filler (D) is not particularly limited, and is preferably 0.1 to 8 μm, more preferably 0.3 to 5 μm. Here, the average particle size is the volume average particle size as described above, and examples thereof include volume-based cumulative 50% diameter (D50) in the laser diffraction/scattering particle size distribution measurement. The specific gravity of the silica filler (D) is not particularly limited, and is preferably 2 to 3 g/em³.

### (Content)

The content ratio of the high dielectric constant filler (C) to the silica filler (D) is 10:90 to 90:10, preferably 15:85 to 85:15, more preferably 20:80 to 80:20 as a mass ratio. In other words, the content of the high dielectric constant filler (C) is 10 to 90 parts by mass, preferably 15 to 85 parts by mass, more preferably 20 to 80 parts by mass with respect to 100 parts by mass of the sum of the high dielectric constant filler (C) and the silica filler (D).

The content of the high dielectric constant filler (C) is preferably 20 to 300 parts by mass, more preferably 25 to 250 parts by mass, still more preferably 30 to 200 parts by mass with respect to 100 parts by mass of the sum of the polyfunctional vinyl aromatic copolymer (A) and the curing agent (B).

When the content of the high dielectric constant filler (C) is in the above range with respect to the sum of the high dielectric constant filler (C) and the silica filler (D) and in the above range with respect to the sum of the polyfunctional vinyl aromatic copolymer (A) and the curing agent (B), a cured product having a high relative dielectric constant and a low dielectric loss tangent is obtained as cured products of the resin composition and prepreg obtained. When the total content of the high dielectric constant filler (C) and the silica filler (D) is too high, the melt viscosity of the obtained resin composition is too high and the moldability tends to decrease. Hence, when the content of the high dielectric constant filler (C) is in the above ranges, excellent moldability and the like are exhibited and a cured product having a high relative dielectric constant and a low dielectric loss tangent is suitably obtained as cured products of the resin composition and prepreg obtained.

The content of the polyfunctional vinyl aromatic copolymer (A) is preferably 30 to 90 parts by mass, more preferably 40 to 80 parts by mass with respect to 100 parts by mass of the sum of the polyfunctional vinyl aromatic copolymer (A) and the curing agent (B). In other words, the content of the curing agent (B) is preferably 10 to 70 parts by mass, more preferably 20 to 60 parts by mass with respect to 100 parts by mass of the sum of the polyfunctional vinyl aromatic copolymer (A) and the curing agent (B). When the content of the curing agent is too low or too high, it tends to be difficult to obtain a suitable cured product of the resin composition, for example, it tends to be difficult to obtain a resin composition exhibiting excellent heat resistance. From this fact, when the content of each of the polyfunctional vinyl aromatic copolymer (A) and the curing agent (B) is in the above range, a cured product having a high relative dielectric constant and a low dielectric loss tangent is suitably obtained.

### (Other Components)

The resin composition may contain components (other components) other than the polyfunctional vinyl aromatic copolymer (A), the curing agent (B), the high dielectric constant filler (C), and the silica filler (D), if necessary, as long as the effects of the present invention are not impaired. As the other components contained in the resin composition according to the present embodiment, for example, additives such as a reaction initiator, a reaction accelerator, a catalyst, a polymerization retarder, a polymerization inhibitor, a dispersant, a leveling agent, a coupling agent, an antifoaming agent, an antioxidant, a heat stabilizer, an antistatic agent, an ultraviolet absorber, a dye or a pigment, and a lubricant may be further contained.

As described above, the resin composition according to the present embodiment may contain a reaction initiator. The curing reaction can proceed even though the resin composition does not contain a reaction initiator. However, a reaction initiator may be added since there is a case where it is difficult to raise the temperature until curing proceeds depending on the process conditions. The reaction initiator is not particularly limited as long as it can promote the curing reaction of the resin composition, and examples thereof include a peroxide and an organic azo compound. Examples of the peroxide include dicumyl peroxide, α,α′-bis(t-butylperoxy-m-isopropyl)benzene, 2,5-dimethyl-2,5-di(t-butylperoxy)-3-hexyne, and benzoyl peroxide. Examples of the organic azo compound include azobisisobutyronitrile. A metal carboxylate can be concurrently used if necessary. By doing so, the curing reaction can be further promoted. Among these, α,α′-bis(t-butylperoxy-m-isopropyl)benzene is preferably used. α,α′-Bis(t-butylperoxy-m-isopropyl)benzene has a relatively high reaction initiation temperature and thus can suppress the promotion of the curing reaction at the time point at which curing is not required, for example, at the time of prepreg drying, and can suppress a decrease in storage stability of the resin composition. α,α′-Bis(t-butylperoxy-m-isopropyl)benzene exhibits low volatility, thus does not volatilize at the time of prepreg drying and storage, and exhibits favorable stability. The reaction initiators may be used singly or in combination of two or more thereof.

As described above, the resin composition according to the present embodiment may contain a coupling agent. The coupling agent may be contained in the resin composition or may be contained as a coupling agent covered on the high dielectric constant filler (C) and silica filler (D) contained in the resin composition for surface treatment in advance. Among these, it is preferable that the coupling agent is contained as a coupling agent covered on the high dielectric constant filler (C) and silica filler (D) for surface treatment in advance, and it is more preferable that the coupling agent is contained as a coupling agent covered on the high dielectric constant filler (C) and silica filler (D) for surface treatment in advance and further is also contained in the resin composition. In the case of a prepreg, the coupling agent may be contained in the prepreg as a coupling agent covered on the fibrous base material for surface treatment in advance. Examples of the coupling agent include those similar to the coupling agents used in the surface treatment of the high dielectric constant filler (C) and silica filler (D) described above.

As described above, the resin composition according to the present embodiment may contain a flame retardant. The flame retardancy of a cured product of the resin composition can be enhanced by containing a flame retardant. The flame retardant is not particularly limited. Specifically, in the field in which halogen-based flame retardants such as bromine-based flame retardants are used, for example, ethylenedipentabromobenzene, ethylenebistetrabromoimide, decabromodiphenyloxide, and tetradecabromodiphenoxybenzene that have a melting point of 300° C. or more, and a bromostyrene-based compound that reacts with the polymerizable compound are preferable. It is considered that the elimination of halogen at a high temperature and the decrease in heat resistance can be suppressed by the use of a halogen-based flame retardant. There is a case where a flame retardant containing phosphorus (phosphorus-based flame retardant) is used in fields required to be halogen-free. The phosphorus-based flame retardant is not particularly limited, and examples thereof include a phosphate ester-based flame retardant, a phosphazene-based flame retardant, a bis(diphenylphosphine oxide)-based flame retardant, and a phosphinate-based flame retardant. Specific examples of the phosphate ester-based flame retardant include a condensed phosphate ester such as dixylenyl phosphate. Specific examples of the phosphazene-based flame retardant include phenoxyphosphazene. Specific examples of the bis(diphenylphosphine oxide)-based flame retardant include xylylenebis(diphenylphosphine oxide). Specific examples of the phosphinate-based flame retardant include metal phosphinates such as an aluminum dialkyl phosphinate. As the flame retardant, the respective flame retardants exemplified may be used singly or in combination of two or more kinds thereof.

### (Use)

The resin composition is used when a prepreg is manufactured, as described later. The resin composition is used when a resin layer included in a metal foil with resin and a film with resin is formed and when an insulating layer included in a metal-clad laminate and a wiring board is formed.

The relative dielectric constant of a cured product of the resin composition is preferably 3.5 to 7, more preferably 3.5 to 6.5 at a frequency of 10 GHz. The dielectric loss tangent of a cured product of the resin composition is preferably 0.01 or less, more preferably 0.005 or less, still more preferably 0.002 or less at a frequency of 10 GHz. The relative dielectric constant and dielectric loss tangent here are the relative dielectric constant and dielectric loss tangent of a cured product of the resin composition at a frequency of 10 GHz, and examples thereof include the relative dielectric constant and dielectric loss tangent of a cured product of the resin composition at a frequency of 10 GHz measured by the cavity perturbation method. The resin composition thus affords a cured product having a high relative dielectric constant and a low dielectric loss tangent. For this reason, the resin composition is suitably used to form an insulating layer included in a multilayer wiring board. In the multilayer wiring board, the total number (the number of wiring layers) of wirings disposed between the insulating layers and the wirings disposed on the insulating layer is not particularly limited, but is, for example, more preferably 10 layers or more, still more preferably 12 layers or more. The density of wiring in a multilayer wiring board can be thus increased, and speeding up of signal transmission can be realized and the signal transmission loss can be decreased in such a multilayer wiring board as well. By the wiring board, speeding up of signal transmission can be realized and the signal transmission loss can be decreased in a case where conductive through holes are equipped, a case where conductive vias are equipped, or a case where conductive through holes and conductive vias are both equipped in a multilayer wiring board. In other words, the resin composition is preferably used to form an insulating layer included between the wiring layers in a wiring board including 10 or more wiring layers.

The multilayer wiring board is not particularly limited, but preferably includes, for example, a wiring pattern having a small distance between wirings and a small wiring width.

The multilayer wiring board is not particularly limited, but includes, for example, preferably a wiring pattern in which the distance between wirings is 380 μm or less, more preferably a wiring pattern in which the distance between wirings is 300 μm or less at a part of the wiring patterns in the multilayer wiring board. In other words, the resin composition is suitably used when a wiring board including a wiring pattern having such a small distance between wirings at a part is manufactured. In the case of a wiring board including a wiring pattern in which the distance between wirings is 380 μm or less at a part as well, speeding up of signal transmission can be realized and the signal transmission loss can be decreased. Here, the distance between wirings is the distance between adjacent wirings.

The multilayer wiring board is not particularly limited, but for example, includes preferably a wiring pattern having a wiring width of 250 μm or less, more preferably a wiring pattern having a width between wirings of 200 μm or less at a part of the wiring patterns in the multilayer wiring board. In other words, the resin composition is suitably used when a wiring board including a wiring pattern having such a small wiring width at a part is manufactured. In the case of a wiring board including a wiring pattern having a wiring width of 250 μm or less as well, speeding up of signal transmission can be realized and the signal transmission loss can be decreased. Here, the wiring width is the distance of the wiring perpendicular to the longitudinal direction.

Conductor through holes and vias may be formed in the multilayer wiring board, if necessary, for conductive connection between the multilayer wiring layers. In the multilayer wiring board, only conductor through holes may be formed, only vias may be formed, or both of these may be formed. The conductor through holes and the vias may each be formed if necessary, and the number thereof may be one or plural. The conductor through holes and the vias are not particularly limited, but preferably have a via diameter of 300 μm or less. In other words, the multilayer wiring board is, for example, preferably a wiring board having a wiring pattern in which conductor through holes with a via diameter of 300 μm or less and vias with a via diameter of 300 μm or less are formed at apart. The multilayer wiring board is more preferably a wiring board having a wiring pattern in which the distances between conductor through holes and vias (for example, distance between conductor through holes, distance between vias, and distance between conductor through holes and vias) are 300 μm or less.

(Production method) The method for producing the resin composition is not particularly limited as long as the resin composition can be produced, and examples thereof include a method in which the polyfunctional vinyl aromatic copolymer (A), the curing agent (B), the high dielectric constant filler (C), and the silica filler (D) are mixed together so as to have predetermined contents. Examples thereof include the method to be described later in the case of obtaining a varnish-like composition containing an organic solvent.

Moreover, by using the resin composition according to the present embodiment, a prepreg, a metal-clad laminate, a wiring board, a metal foil with resin, and a film with resin can be obtained as described below.

### [Prepreg]

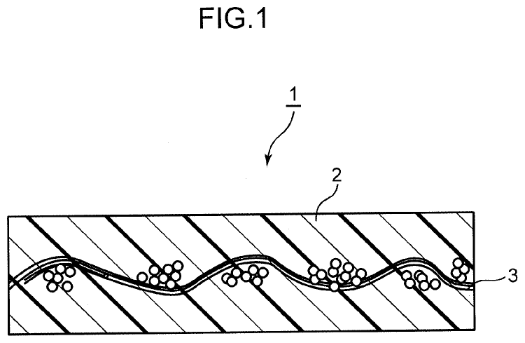

FIG. 1 is a schematic sectional view illustrating an example of a prepreg 1 according to an embodiment of the present invention.

As illustrated in FIG. 1, the prepreg 1 according to the present embodiment includes the resin composition or a semi-cured product 2 of the resin composition and a fibrous base material 3. This prepreg 1 includes the resin composition or the semi-cured product 2 of the resin composition and the fibrous base material 3 present in the resin composition or the semi-cured product 2 of the resin composition.

In the present embodiment, the semi-cured product is in a state in which the resin composition has been cured to an extent that the resin composition can be further cured. In other words, the semi-cured product is the resin composition in a semi-cured state (B-staged). For example, when a resin composition is heated, the viscosity of the resin composition first gradually decreases, then curing starts, and the viscosity gradually increases. In such a case, the semi-cured state includes a state in which the viscosity has started to increase but curing is not completed, and the like.

The prepreg to be obtained using the resin composition according to the present embodiment may include a semi-cured product of the resin composition as described above or include the uncured resin composition itself. In other words, the prepreg may be a prepreg including a semi-cured product of the resin composition (the resin composition in B stage) and a fibrous base material or a prepreg including the resin composition before being cured (the resin composition in A stage) and a fibrous base material. The resin composition or a semi-cured product of the resin composition may be one obtained by drying or heating and drying the resin composition.

When a prepreg is manufactured, the resin composition 2 is often prepared in a varnish form and used in order to be impregnated into the fibrous base material 3 which is a base material for forming the prepreg. In other words, the resin composition 2 is usually a resin varnish prepared in a varnish form in many cases. Such a varnish-like resin composition (resin varnish) is prepared, for example, as follows.

First, the respective components which can be dissolved in an organic solvent are introduced into and dissolved in an organic solvent. At this time, heating may be performed if necessary. Thereafter, components which are used if necessary but are not dissolved in the organic solvent are added to and dispersed in the solution until a predetermined dispersion state is achieved using a ball mill, a bead mill, a planetary mixer, a roll mill or the like, whereby a varnish-like resin composition is prepared. The organic solvent used here is not particularly limited as long as it dissolves the polyfunctional vinyl aromatic copolymer (A), the curing agent (B) and the like, and does not inhibit the curing reaction. Specific examples thereof include toluene and methyl ethyl ketone (MEK).

Specific examples of the fibrous base material include glass cloth, aramid cloth, polyester cloth, a glass nonwoven fabric, an aramid nonwoven fabric, a polyester nonwoven fabric, pulp paper, and linter paper. When glass cloth is used, a laminate exhibiting excellent mechanical strength is obtained, and glass cloth subjected to flattening is particularly preferable. Specific examples of the flattening include a method in which glass cloth is continuously pressed at an appropriate pressure using a press roll to flatly compress the yarn. The thickness of the generally used fibrous base material is, for example, 0.01 mm or more and 0.3 mm or less. The glass fiber constituting the glass cloth is not particularly limited, and examples thereof include Q glass, NE glass, E glass, S glass, T glass, L glass, and L2 glass. The surface of the fibrous base material may be subjected to a surface treatment with a silane coupling agent. The silane coupling agent is not particularly limited, but examples thereof include a silane coupling agent having at least one selected from the group consisting of a vinyl group, an acryloyl group, a methacryloyl group, a styryl group, an amino group, and an epoxy group in the molecule.

The relative dielectric constant of the fibrous base material is preferably 3.5 to 7, more preferably 3.5 to 6.5 at a frequency of 10 GHz. The difference between the relative dielectric constant of a cured product of the resin composition at a frequency of 10 GHz and the relative dielectric constant of the fibrous base material at a frequency of 10 GHz is preferably 0 to 0.3, more preferably 0 to 0.2, still more preferably 0. When the relative dielectric constant of the fibrous base material is in the above range, the occurrence of skew in the finally obtained wiring board can be suppressed. Therefore, deterioration in signal quality due to skew in the wiring board can be suppressed. The dielectric loss tangent of the fibrous base material is preferably 0.0002 to 0.01, more preferably 0.0005 to 0.008 at a frequency of 10 GHz. The relative dielectric constant of a cured product of the prepreg is preferably 3.5 to 7, more preferably 3.5 to 6.5 at a frequency of 10 GHz.

The relative dielectric constant (Dk) and dielectric loss tangent (Df) of the fibrous base material are values determined by the following measurement methods. First, a substrate (copper-clad laminate) is fabricated so that the resin content per 100% by mass of prepreg is 60% by mass, the copper foil is removed from the fabricated copper-clad laminate to obtain a sample for evaluation of relative dielectric constant (Dk) and dielectric loss tangent (Df). Dk and Df of the obtained sample at a frequency of 10 GHz were measured by the cavity perturbation method using a network analyzer (N5230A manufactured by Agilent Technologies, Inc.). Dk and Df of the fibrous base material are calculated based on Dk and Df of the obtained sample (the cured product of the prepreg), the volume fraction of the fibrous base material, and Dk and Df of a cured product of the resin composition used in the substrate fabrication at a frequency of 10 GHz measured by the cavity perturbation method.

The method for manufacturing the prepreg is not particularly limited as long as the prepreg can be manufactured. Specifically, when the prepreg is manufactured, the resin composition according to the present embodiment described above is often prepared in a varnish form and used as a resin varnish as described above.

Specific examples of the method for manufacturing the prepreg 1 include a method in which the fibrous base material 3 is impregnated with the resin composition 2, for example, the resin composition 2 prepared in a varnish form, and then dried. The fibrous base material 3 is impregnated with the resin composition 2 by dipping, coating, and the like. If necessary, the impregnation can be repeated a plurality of times. Moreover, at this time, it is also possible to finally adjust the composition and impregnated amount to the desired composition and impregnated amount by repeating impregnation using a plurality of resin compositions having different compositions and concentrations.

The fibrous base material 3 impregnated with the resin composition (resin varnish) 2 is heated under desired heating conditions, for example, at 40° C. or more and 180° C. or less for 1 minute or more and 10 minutes or less. By heating, the prepreg 1 before being cured (A-stage) or in a semi-cured state (B-stage) is obtained. By the heating, the organic solvent can be decreased or removed by being volatilized from the resin varnish.

The resin composition according to the present embodiment is a resin composition, which affords a cured product having a high relative dielectric constant, a low dielectric loss tangent, and excellent heat resistance. For this reason, the prepreg including this resin composition or a semi-cured product of this resin composition is a prepreg, which affords a cured product having a high relative dielectric constant, a low dielectric loss tangent, and excellent heat resistance. Moreover, a wiring board including an insulating layer containing a cured product, which has a high relative dielectric constant, a low dielectric loss tangent, and excellent heat resistance, can be suitably manufactured using this prepreg. As a cured product obtained from the resin composition, there is obtained a cured product having not only a high relative dielectric constant, a low dielectric loss tangent, and excellent heat resistance but also a low coefficient of thermal expansion. For this reason, a cured product having a low coefficient of thermal expansion is obtained as a cured product of the prepreg. Hence, a wiring board obtained from this prepreg includes an insulating layer having not only a high relative dielectric constant and a low dielectric loss tangent but also excellent heat resistance and a low coefficient of thermal expansion.

### [Metal-Clad Laminate]

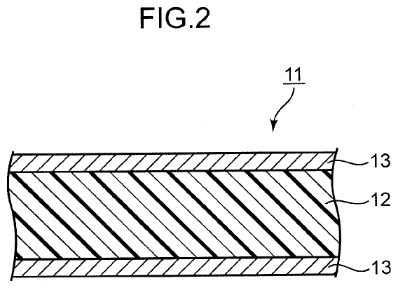

FIG. 2 is a schematic sectional view illustrating an example of a metal-clad laminate 11 according to an embodiment of the present invention.

As illustrated in FIG. 2, the metal-clad laminate 11 according to the present embodiment includes an insulating layer 12 containing a cured product of the resin composition and a metal foil 13 provided on the insulating layer 12. Examples of the metal-clad laminate 11 include a metal-clad laminate including an insulating layer 12 containing a cured product of the prepreg 1 illustrated in FIG. 1 and a metal foil 13 to be laminated together with the insulating layer 12. The insulating layer 12 may be formed of a cured product of the resin composition or a cured product of the prepreg. In addition, the thickness of the metal foil 13 varies depending on the performance and the like to be required for the finally obtained wiring board and is not particularly limited. The thickness of the metal foil 13 can be appropriately set depending on the desired purpose and is preferably, for example, 0.2 to 70 μm. Examples of the metal foil 13 include a copper foil and an aluminum foil, and the metal foil 13 may be a copper foil with carrier which includes a release layer and a carrier for the improvement in handleability in a case where the metal foil is thin.

The method for manufacturing the metal-clad laminate 11 is not particularly limited as long as the metal-clad laminate 11 can be manufactured. Specific examples thereof include a method in which the metal-clad laminate 11 is fabricated using the prepreg 1. Examples of this method include a method in which the double-sided metal foil-clad or single-sided metal foil-clad laminate 11 is fabricated by stacking one sheet or a plurality of sheets of prepreg 1, further stacking the metal foil 13 such as a copper foil on both or one of upper and lower surfaces of the prepregs 1, and laminating and integrating the metal foils 13 and prepregs 1 by heating and pressing. In other words, the metal-clad laminate 11 is obtained by laminating the metal foil 13 on the prepreg 1 and then performing heating and pressing. The heating and pressing conditions can be appropriately set depending on the thickness of the metal-clad laminate 11, the kind of the resin composition contained in the prepreg 1, and the like. For example, it is possible to set the temperature to 170° C. to 230° C., the pressure to 2 to 4 MPa, and the time to 60 to 150 minutes. Moreover, the metal-clad laminate may be manufactured without using a prepreg. Examples thereof include a method in which a varnish-like resin composition is applied on a metal foil to form a layer containing the resin composition on the metal foil and then heating and pressing is performed.

The resin composition according to the present embodiment is a resin composition, which affords a cured product having a high relative dielectric constant, a low dielectric loss tangent, and excellent heat resistance. For this reason, the metal-clad laminate including an insulating layer containing a cured product of this resin composition is a metal-clad laminate including an insulating layer containing a cured product, which has a high relative dielectric constant, a low dielectric loss tangent, and excellent heat resistance. Moreover, a wiring board including an insulating layer containing a cured product, which has a high relative dielectric constant, a low dielectric loss tangent, and excellent heat resistance, can be suitably manufactured using this metal-clad laminate. As a cured product obtained from the resin composition, there is obtained a cured product having not only a high relative dielectric constant, a low dielectric loss tangent, and excellent heat resistance but also a low coefficient of thermal expansion. For this reason, a wiring board obtained using a metal-clad laminate including an insulating layer containing a cured product of the resin composition includes an insulating layer having not only a high relative dielectric constant and a low dielectric loss tangent but also excellent heat resistance and a low coefficient of thermal expansion.

### [Wiring Board]

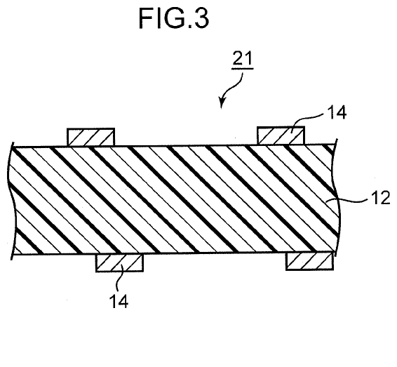

FIG. 3 is a schematic sectional view illustrating an example of a wiring board 21 according to an embodiment of the present invention.

The wiring board 21 according to the present embodiment includes an insulating layer 12 containing a cured product of the resin composition and wiring 14 provided on the insulating layer 12. Examples of the wiring board 21 include a wiring board including the insulating layer 12 and the wiring 14 disposed so as to be in contact with both surfaces of the insulating layer 12 as illustrated in FIG. 3. The wiring board may be a wiring board in which the wiring is equipped in contact with only one surface of the insulating layer. Examples of the wiring board 21 include a wiring board formed of an insulating layer 12 obtained by curing the prepreg 1 illustrated in FIG. 1 and wiring 14 which is laminated together with the insulating layer 12 and is formed by partially removing the metal foil 13. The insulating layer 12 may be formed of a cured product of the resin composition or a cured product of the prepreg.

The method for manufacturing the wiring board 21 is not particularly limited as long as the wiring board 21 can be manufactured. Specific examples thereof include a method in which the wiring board 21 is fabricated using the prepreg 1. Examples of this method include a method in which the wiring board 21, in which wiring is provided as a circuit on the surface of the insulating layer 12, is fabricated by forming wiring through etching and the like of the metal foil 13 on the surface of the metal-clad laminate 11 fabricated in the manner described above. In other words, the wiring board 21 is obtained by partially removing the metal foil 13 on the surface of the metal-clad laminate 11 and thus forming a circuit. Examples of the method for forming a circuit include circuit formation by a semi-additive process (SAP) or a modified semi-additive process (MSAP) in addition to the method described above. The wiring board 21 is a wiring board including the insulating layer 12 containing a cured product, which has a high relative dielectric constant, a low dielectric loss tangent, and excellent heat resistance. As a cured product obtained from the resin composition, there is obtained a cured product having not only a high relative dielectric constant, a low dielectric loss tangent, and excellent heat resistance but also a low coefficient of thermal expansion. For this reason, the wiring board includes an insulating layer having not only a high relative dielectric constant and a low dielectric loss tangent but also excellent heat resistance and a low coefficient of thermal expansion.

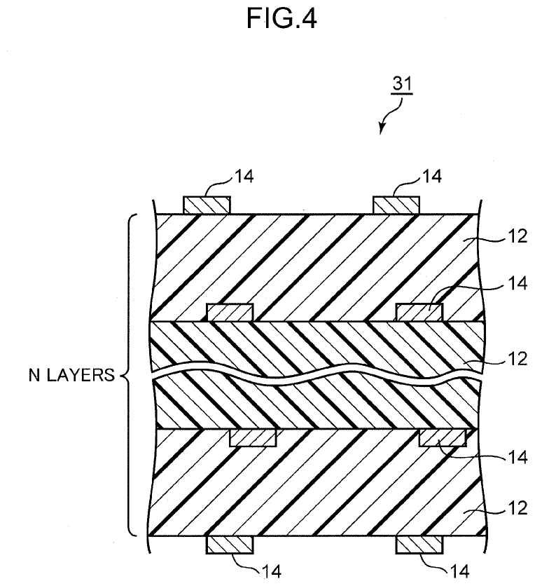

The wiring board may be a wiring board in which the wiring is one layer and the insulating layer is one layer, or may be the wiring board 21 in which the wiring is two layers and the insulating layer is one layer as illustrated in FIG. 3. The wiring board may be a multilayer wiring board 31 in which both the wiring and the insulating layer are multiple layers as illustrated in FIG. 4. In this multilayer wiring board 31, the wiring 14 may be disposed between the insulating layers 12 or may be disposed on the surface of the insulating layer 12. The resin composition affords a cured product having a high relative dielectric constant, a low dielectric loss tangent, and excellent heat resistance as described above, and is suitably used when an insulating layer included in such a multilayer wiring board 31 is formed. In other words, the wiring board includes an insulating layer containing a cured product of the resin composition and is preferably a multilayer wiring board. FIG. 4 is a schematic sectional view illustrating another example of the wiring board 31 according to an embodiment of the present invention.

The multilayer wiring board 31 is a wiring board in which both the wiring 14 and the insulating layer 12 are multiple layers as described above, and the total number of wirings 14 disposed between the insulating layers 12 and the wirings 14 disposed on the insulating layer 12 (the number of wiring layers, namely, N layers) is not particularly limited, but is preferably 10 layers or more, preferably 12 layers or more. The density of wiring in a multilayer wiring board can be thus increased, and speeding up of signal transmission can be realized and the signal transmission loss can be decreased in such a multilayer wiring board as well. By the wiring board, speeding up of signal transmission can be realized and the signal transmission loss can be decreased in a case where conductive through holes are equipped, a case where conductive vias are equipped, or a case where conductive through holes and conductive vias are both equipped in a multilayer wiring board. In the multilayer wiring board, a wiring board in which the distance between wirings and the wiring width are in the ranges described above is more preferable.

The multilayer wiring board 31 is manufactured, for example, as follows. The prepreg is laminated on at least one surface of the wiring board 21 as illustrated in FIG. 3, a metal foil is further laminated thereon if necessary, and heating and pressing is performed. Wiring is formed by performing etching of the metal foil on the surface of the laminate thus obtained, and the like. In this manner, the multilayer wiring board 31 as illustrated in FIG. 4 can be manufactured.

[Metal Foil with Resin]

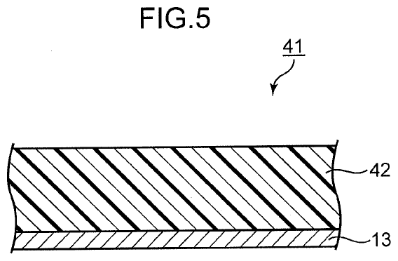

FIG. 5 is a schematic sectional view illustrating an example of a metal foil with resin 41 according to the present embodiment.

The metal foil with resin 41 according to the present embodiment includes a resin layer 42 containing the resin composition or a semi-cured product of the resin composition and a metal foil 13 as illustrated in FIG. 5. The metal foil with resin 41 includes the metal foil 13 on the surface of the resin layer 42. In other words, the metal foil with resin 41 includes the resin layer 42 and the metal foil 13 to be laminated together with the resin layer 42. The metal foil with resin 41 may include other layers between the resin layer 42 and the metal foil 13.

The resin layer 42 may contain a semi-cured product of the resin composition as described above or may contain the uncured resin composition. In other words, the metal foil with resin 41 may be a metal foil with resin including a resin layer containing a semi-cured product of the resin composition (the resin composition in B stage) and a metal foil or a metal foil with resin including a resin layer containing the resin composition before being cured (the resin composition in A stage) and a metal foil. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the metal foil, metal foils used in metal-clad laminates or metal foils with resin can be used without limitation. Examples of the metal foil include a copper foil and an aluminum foil.

The metal foil with resin 41 may include a cover film and the like if necessary. By including a cover film, it is possible to prevent entry of foreign matter and the like. The cover film is not particularly limited, and examples thereof include a polyolefin film, a polyester film, a polymethylpentene film, and films formed by providing a release agent layer on these films.

The method for manufacturing the metal foil with resin 41 is not particularly limited as long as the metal foil with resin 41 can be manufactured. Examples of the method for manufacturing the metal foil with resin 41 include a method in which the varnish-like resin composition (resin varnish) is applied on the metal foil 13 and heated to manufacture the metal foil with resin 41. The varnish-like resin composition is applied on the metal foil 13 using, for example, a bar coater. The applied resin composition is heated under the conditions of, for example, 40° C. or more and 180° C. or less and 0.1 minute or more and 10 minutes or less. The heated resin composition is formed as the uncured resin layer 42 on the metal foil 13. By the heating, the organic solvent can be decreased or removed by being volatilized from the resin varnish.

The resin composition according to the present embodiment is a resin composition, which affords a cured product having a high relative dielectric constant, a low dielectric loss tangent, and excellent heat resistance. For this reason, the metal foil with resin including a resin layer containing this resin composition or a semi-cured product of this resin composition is a metal foil with resin including a resin layer, which affords a cured product having a high relative dielectric constant, a low dielectric loss tangent, and excellent heat resistance. Moreover, this metal foil with resin can be used when a wiring board including an insulating layer containing a cured product, which has a high relative dielectric constant, a low dielectric loss tangent, and excellent heat resistance, is manufactured. For example, by laminating the metal foil with resin on a wiring board, a multilayer wiring board can be manufactured. As a wiring board obtained using such a metal foil with resin, there is obtained a wiring board including an insulating layer containing a cured product, which has a high relative dielectric constant, a low dielectric loss tangent, and excellent heat resistance. As a cured product obtained from the resin composition, there is obtained a cured product having not only a high relative dielectric constant, a low dielectric loss tangent, and excellent heat resistance but also a low coefficient of thermal expansion. For this reason, a wiring board obtained using a metal foil with resin including a resin layer containing the resin composition or a semi-cured product of the resin composition includes an insulating layer having not only a high relative dielectric constant and a low dielectric loss tangent but also excellent heat resistance and a low coefficient of thermal expansion.

[Film with Resin]

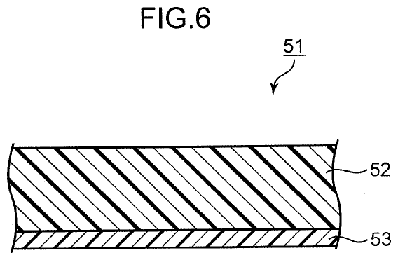

FIG. 6 is a schematic sectional view illustrating an example of a film with resin 51 according to the present embodiment.

The film with resin 51 according to the present embodiment includes a resin layer 52 containing the resin composition or a semi-cured product of the resin composition and a support film 53 as illustrated in FIG. 6. The film with resin 51 includes the resin layer 52 and the support film 53 to be laminated together with the resin layer 52. The film with resin 51 may include other layers between the resin layer 52 and the support film 53.

The resin layer 52 may contain a semi-cured product of the resin composition as described above or may contain the uncured resin composition. In other words, the film with resin 51 may be a film with resin including a resin layer containing a semi-cured product of the resin composition (the resin composition in B stage) and a support film or a film with resin including a resin layer containing the resin composition before being cured (the resin composition in A stage) and a support film. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the support film 53, support films used in films with resin can be used without limitation. Examples of the support film include electrically insulating films such as a polyester film, a polyethylene terephthalate (PET) film, a polyimide film, a polyparabanic acid film, a polyether ether ketone film, a polyphenylene sulfide film, a polyamide film, a polycarbonate film, and a polyarylate film.

The film with resin 51 may include a cover film and the like if necessary. By including a cover film, it is possible to prevent entry of foreign matter and the like. The cover film is not particularly limited, and examples thereof include a polyolefin film, a polyester film, and a polymethylpentene film.

The support film and the cover film may be those subjected to surface treatments such as a matt treatment, a corona treatment, a release treatment, and a roughening treatment if necessary.

The method for manufacturing the film with resin 51 is not particularly limited as long as the film with resin 51 can be manufactured. Examples of the method for manufacturing the film with resin 51 include a method in which the varnish-like resin composition (resin varnish) is applied on the support film 53 and heated to manufacture the film with resin 51. The varnish-like resin composition is applied on the support film 53 using, for example, a bar coater. The applied resin composition is heated under the conditions of, for example, 40° C. or more and 180° C. or less and 0.1 minute or more and 10 minutes or less. The heated resin composition is formed as the uncured resin layer 52 on the support film 53. By the heating, the organic solvent can be decreased or removed by being volatilized from the resin varnish.

The resin composition according to the present embodiment is a resin composition, which affords a cured product having a high relative dielectric constant, a low dielectric loss tangent, and excellent heat resistance. For this reason, the film with resin including a resin layer containing this resin composition or a semi-cured product of this resin composition is a film with resin including a resin layer, which affords a cured product having a high relative dielectric constant, a low dielectric loss tangent, and excellent heat resistance. Moreover, this film with resin can be used when a wiring board including an insulating layer containing a cured product, which has a high relative dielectric constant, a low dielectric loss tangent, and excellent heat resistance, is suitably manufactured. A multilayer wiring board can be manufactured, for example, by laminating the film with resin on a wiring board and then peeling off the support film from the film with resin or by peeling off the support film from the film with resin and then laminating the film with resin on a wiring board. As a wiring board obtained using such a film with resin, there is obtained a wiring board including an insulating layer containing a cured product, which has a high relative dielectric constant, a low dielectric loss tangent, and excellent heat resistance. As a cured product obtained from the resin composition, there is obtained a cured product having not only a high relative dielectric constant, a low dielectric loss tangent, and excellent heat resistance but also a low coefficient of thermal expansion. For this reason, a wiring board obtained using a film with resin including a resin layer containing the resin composition or a semi-cured product of the resin composition includes an insulating layer having not only a high relative dielectric constant and a low dielectric loss tangent but also excellent heat resistance and a low coefficient of thermal expansion.

According to the present invention, it is possible to provide a resin composition, which affords a cured product having a high relative dielectric constant, a low dielectric loss tangent, and excellent heat resistance. According to the present invention, it is possible to provide a prepreg, a film with resin, a metal foil with resin, a metal-clad laminate, and a wiring board, which are obtained using the resin composition.

Hereinafter, the present invention will be described more specifically with reference to examples, but the scope of the present invention is not limited thereto.

### EXAMPLES

### Examples 1 to 11 and Comparative Examples 1 to 4

The respective components used when a prepreg is fabricated in the present Examples will be described.

### (Polyfunctional Vinyl Aromatic Copolymer (A))

Polyfunctional vinyl aromatic copolymer: This is a polyfunctional vinyl aromatic copolymer obtained by conducting a reaction as follows.

Into a 5.0 L reactor, 2.25 mole (292.9 g) of divinylbenzene, 1.32 mole (172.0 g) of ethylvinylbenzene, 11.43 mole (1190.3 g) of styrene and 15.0 mole (1532.0 g) of n-propyl acetate were charged, 600 mmole of boron trifluoride diethyl ether complex was added at 70° C., and the reaction was conducted for 4 hours. After that, an aqueous sodium bicarbonate solution was added to the obtained reaction mixture in order to stop the reaction, and then the oil layer was washed three times with pure water and volatilized under reduced pressure at 60° C. to recover the solid. The obtained solid was weighed to confirm that 860.8 g was obtained.

The molecular weight and molecular weight distribution measurement of the obtained solid (polymer) was performed using tetrahydrofuran as a solvent and a calibration curve created using monodisperse polystyrene at a flow rate of 1.0 ml/min and a column temperature of 38° C. using GPC (HLC-8120GPC manufactured by Tosoh Corporation). As a result, the obtained solid had a number average molecular weight Mn of 2060, a weight average molecular weight Mw of 30700, and Mw/Mn of 14.9.

The structure of the obtained solid (polymer) was measured by ¹³C-NMR and ¹H-NMR analysis using a nuclear magnetic resonance spectrometer, Model JNM-LA600 manufactured by JEOL Ltd. Chloroform-di was used as the solvent and the resonance line of tetramethylsilane was used as the internal standard. In addition to the ¹³C-NMR and ¹H-NMR measurement results, the amount of a specific structural unit introduced was calculated from the data on the total amount of the respective structural units introduced into the copolymer acquired by GC analysis, and the amount of the pendant vinyl group units contained in the polyfunctional vinyl aromatic copolymer was calculated from the amount of the specific structural unit introduced at the terminal and the number average molecular weight acquired by the GPC measurement.

The obtained solid was subjected to ¹³C-NMR and ¹H-NMR analysis as described above to observe resonance lines derived from each monomer unit. Based on the results of NMR measurement and the results of GC analysis, it was found that this solid was the polyfunctional vinyl aromatic copolymer. The structural units of this polyfunctional vinyl aromatic copolymer were calculated as follows based on the results of NMR measurement and the results of GC analysis. The structural unit (a) derived from divinylbenzene was 20.9 mol % (24.3 wt %), the structural unit (b1) derived from styrene was 70.0 mol % (65.0 wt %), the structural unit (b2) derived from ethylvinylbenzene was 9.1 mol % (10.7 wt %), and the structural unit (a1) having a residual vinyl group derived from divinylbenzene was 16.7 mol % (18.5 wt %).

### (Curing Agent (B))

Acenaphthylene: Acenaphthylene manufactured by JFE Chemical Corporation
DVB: Divinylbenzene (DVB810 manufactured by NIPPON STEEL CORPORATION)
TAIC: Triallyl isocyanurate (TAIC manufactured by Nihon Kasei Co., Ltd.)
Modified PPE: This is a polyphenylene ether compound (vinylbenzyl-modified polyphenylene ether) having a vinylbenzyl group (ethenylbenzyl group) at the terminal. Specifically, this is a modified polyphenylene ether compound obtained by reacting polyphenylene ether with chloromethylstyrene.

More specifically, this is a modified polyphenylene ether compound obtained by conducting a reaction as follows.

First, 200 g of polyphenylene ether (SA90 manufactured by SABIC Innovative Plastics Co., Ltd., number of terminal hydroxyl groups: 2, weight average molecular weight Mw: 1700), 30 g of a mixture containing p-chloromethylstyrene and m-chloromethylstyrene at a mass ratio of 50:50 (chloromethylstyrene: CMS manufactured by Tokyo Chemical Industry Co., Ltd.), 1.227 g of tetra-n-butylammonium bromide as a phase transfer catalyst, and 400 g of toluene were introduced into a 1-liter three-necked flask equipped with a temperature controller, a stirrer, cooling equipment, and a dropping funnel and stirred. Then, the mixture was stirred until polyphenylene ether, chloromethylstyrene, and tetra-n-butylammonium bromide were dissolved in toluene. At that time, the mixture was gradually heated until the liquid temperature finally reached 75° C. Thereafter, an aqueous sodium hydroxide solution (20 g of sodium hydroxide/20 g of water) as an alkali metal hydroxide was added dropwise to the solution over 20 minutes. Thereafter, the mixture was further stirred at 75° C. for 4 hours. Next, the resultant in the flask was neutralized with hydrochloric acid at 10% by mass and then a large amount of methanol was added into the flask. By doing so, a precipitate was generated in the liquid in the flask. In other words, the product contained in the reaction solution in the flask was reprecipitated. Thereafter, this precipitate was taken out by filtration, washed three times with a mixed solution of methanol and water contained at a mass ratio of 80:20, and then dried under reduced pressure at 80° C. for 3 hours.

The obtained solid was analyzed by ¹H-NMR (400 MHz, CDCl₃, TMS). As a result of NMR measurement, a peak attributed to a vinylbenzyl group (ethenylbenzyl group) was observed at 5 to 7 ppm. This made it possible to confirm that the obtained solid was a modified polyphenylene ether compound having a vinylbenzyl group (ethenylbenzyl group) as the substituent at the molecular terminal in the molecule. Specifically, the obtained solid was confirmed to be ethenylbenzylated polyphenylene ether (vinylbenzyl-modified polyphenylene ether). The molecular weight distribution of this vinylbenzyl-modified polyphenylene ether was measured using GPC. Moreover, the weight average molecular weight (Mw) was calculated from the obtained molecular weight distribution. As a result, Mw was 1900.

### (High Dielectric Constant Filler (C): Titanate Compound Filler (C1))

Strontium titanate particles-1: Strontium titanate particles not subjected to surface treatment with coupling agent (ST-A manufactured by Fuji Titanium Industry Co., Ltd., specific gravity: 5.1 g/cm³, average particle size (D50): 1.6 μm)
Strontium titanate particles-2: Particles obtained by subjecting strontium titanate particles-1 to surface treatment with silane coupling agent having methacryloyl group (methacrylsilane) (3-methacryloxypropyltrimethoxysilane, KBM-503 manufactured by Shin-Etsu Chemical Co., Ltd.)
Calcium titanate particles: CT manufactured by Fuji Titanium Industry Co., Ltd. (specific gravity: 4 g/cm³, average particle size (D50): 2.1 μm)

### (High Dielectric Constant Filler (C): Magnesium Oxide Filler (C2))

Magnesium oxide particles-1: Magnesium oxide particles not subjected to surface treatment with coupling agent (RF-10CS manufactured by Ube Material Industries Ltd., specific gravity: 3.6 g/cm³, average particle size (D50): 6 μm)

### (Silica Filler (D))

Spherical silica: SC2300-SVJ manufactured by ADMATECHS COMPANY LIMITED (specific gravity: 2.3 g/cm³, average particle size (D50): 0.5 μm)

### (Fibrous Base Material)

Q glass: Quartz glass cloth (SQX Series, #1078 type manufactured by Shin-Etsu Chemical Co., Ltd., relative dielectric constant: 3.5, dielectric loss tangent: 0.0015) L2 glass: L2 glass cloth (L2-1078, #1078 type manufactured by Asahi Kasei Corporation, relative dielectric constant: 4.4, dielectric loss tangent: 0.0018)
NE glass: NE glass cloth (NE1078, #1078 type manufactured by Nitto Boseki Co., Ltd., relative dielectric constant: 4.5, dielectric loss tangent: 0.0038)
E glass: E glass cloth (ND1078, #1078 type manufactured by NAN YA PLASTICS CORPORATION, relative dielectric constant: 6.0, dielectric loss tangent: 0.0060)

### [Preparation Method]

First, the respective components other than the high dielectric constant filler (C), silica filler (D), and aluminum hydroxide particles were added to and mixed in toluene at the compositions (parts by mass) presented in Tables 1 and 2 so that the solid concentration was 50% by mass. The mixture was stirred for 60 minutes. After that, the high dielectric constant filler (C), silica filler (D), and aluminum hydroxide particles were added to the obtained liquid at the compositions (parts by mass) presented in Tables 1 and 2, and dispersed using a bead mill. By doing so, a varnish-like resin composition (varnish) was obtained.

Next, a prepreg and an evaluation substrate 1 (metal-clad laminate) were obtained as follows.

The obtained varnish was impregnated into a fibrous base material (glass cloth) presented in Tables 1 and 2, and then heated and dried at 120° C. to 150° C. for 3 minutes, thereby fabricating a prepreg. At that time, the content (resin content) of the components constituting the resin composition with respect to the prepreg was adjusted to the content so that the thickness of one prepreg sheet was 0.075 mm by the curing reaction.

Next, an evaluation substrate 1 (metal-clad laminate) was obtained as follows.

Copper foil (FV-WS manufactured by Furukawa Electric Co., Ltd., thickness: 18 μm) was disposed on both sides of each of the obtained prepregs. This as a body to be pressed was heated to a temperature of 220° C. at a rate of temperature rise of 3° C./min and heated and pressed under the conditions of 220° C., 90 minutes, and a pressure of 3 MPa, thereby obtaining an evaluation substrate 1 (metal-clad laminate) having a copper foil bonded to both surfaces and a thickness of about 0.075 mm.

An evaluation substrate 2 (metal-clad laminate) not including a fibrous base material was also fabricated in the same manner as the evaluation substrate 1 (metal-clad laminate) except that a fibrous base material was not used.

The evaluation substrate 1 (metal-clad laminate) and evaluation substrate 2 (metal-clad laminate) fabricated as described above were evaluated by the following methods.

### [Dielectric Properties (Relative Dielectric Constant and Dielectric Loss Tangent)]

The relative dielectric constant and dielectric loss tangent at 10 GHz were measured by the cavity perturbation method using unclad substrates obtained by removing the copper foil from the evaluation substrate 1 (metal-clad laminate) and evaluation substrate 2 (metal-clad laminate) by etching as a test piece. Specifically, the relative dielectric constant and dielectric loss tangent of the evaluation substrate at 10 GHz were measured using a network analyzer (N5230A manufactured by Keysight Technologies). The relative dielectric constant and dielectric loss tangent acquired using the evaluation substrate 1 (metal-clad laminate) are measured as the relative dielectric constant and dielectric loss tangent of a cured product of the prepreg since the evaluation substrate 1 includes a fibrous base material. The relative dielectric constant and dielectric loss tangent acquired using the evaluation substrate 2 (metal-clad laminate) are measured as the relative dielectric constant and dielectric loss tangent of a cured product of the resin composition since the evaluation substrate 2 does not include a fibrous base material. A difference was calculated by subtracting the relative dielectric constant of the fibrous base material from the relative dielectric constant of a cured product of the resin composition.

### [Skew: Delay Time Difference]

One metal foil (copper foil) of the evaluation substrate 1 (metal-clad laminate) was processed to form 10 wirings with a line width of 100 to 300 μm, a line length of 100 mm, and a distance between lines of 20 mm. Three sheets of prepreg and metal foil (copper foil) were secondarily laminated on the surface on the side on which the wiring was formed of the substrate on which this wiring was formed, thereby fabricating a three-layer board. The line width of the wiring was adjusted so that the characteristic impedance of the circuit after fabrication of the three-layer board was 50Ω.

The delay time at 20 GHz of the obtained three-layer board was measured. The difference between the maximum value and minimum value of the measured delay times was calculated. The difference thus calculated is the delay time difference, and skew of the differential signal is likely to occur when the delay time difference is large. Therefore, the delay time difference becomes an index for evaluating signal quality due to skew. In other words, there is a tendency that the deterioration in signal quality due to skew is likely to occur when the delay time difference is large and the deterioration in signal quality due to skew is less likely to occur when the delay time difference is small. Hence, as the evaluation of skew, it was evaluated as “O” when the value calculated above (delay time difference) was 0.5 picoseconds or less, it was evaluated as “◯” when the value was more than 0.5 picoseconds and less than 1 picoseconds, and it was evaluated as “X” when the value was 1 picoseconds or more.

### [Coefficient of Thermal Expansion]

First, ten sheets of the prepreg were stacked, and copper foil (FV-WS manufactured by Furukawa Electric Co., Ltd., thickness: 18 μm) was disposed on both sides of the stacked body. This as a body to be pressed was heated to a temperature of 220° C. at a rate of temperature rise of 3° C./min and heated and pressed under the conditions of 220° C., 90 minutes, and a pressure of 3 MPa, thereby obtaining an evaluation substrate 3 (metal-clad laminate) having a copper foil bonded to both surfaces and a thickness of about 0.75 mm. Using an unclad substrate obtained by removing the copper foil from this evaluation substrate 3 by etching as a test piece, the coefficient of thermal expansion (CTE: ppm/° C.) in the Z-axis direction was measured by TMA (thermo-mechanical analysis) in conformity with JIS C 6481. For the measurement, a TMA instrument (TMA6000 manufactured by SII NanoTechnology Inc.) was used, and the measurement was performed in a range of 50° C. to 100° C.

### [Heat Resistance]

Next, an evaluation substrate 4 (10-layer board) was obtained as follows.

First, two sheets of the prepreg were stacked, and copper foil (FV-WS manufactured by Furukawa Electric Co., Ltd., thickness: 18 μm) was disposed on both sides of the stacked body. This as a body to be pressed was heated to a temperature of 210° C. at a rate of temperature rise of 3° C./min and heated and pressed under the conditions of 210° C., 90 minutes, and a pressure of 3 MPa, thereby obtaining a metal-clad laminate having a copper foil bonded to both surfaces. Then, four sheets of this metal-clad laminate were prepared.

Four sheets of the metal-clad laminate and the prepregs were alternately laminated so that the prepreg was on both surfaces. At that time, two sheets of prepreg were laminated between two metal-clad laminates. Then, the copper foil was laminated on both surfaces of the laminated body. This as a body to be pressed was heated to a temperature of 210° C. at a rate of temperature rise of 3° C./min and heated and pressed under the conditions of 210° C., 90 minutes, and a pressure of 3 MPa, thereby obtaining an evaluation substrate 4 (10-layer board). In other words, the layer structure of this evaluation substrate 4 (10-layer board) is copper foil/two sheets of prepreg/metal-clad laminate (copper foil/two sheets of prepreg/copper foil)/two sheets of prepreg/metal-clad laminate/two sheets of prepreg/metal-clad laminate/two sheets of prepreg/metal-clad laminate/two sheets of prepreg/copper foil.

The obtained evaluation substrate 4 (10-layer board) was subjected to reflow treatment in a reflow furnace at 280° C. predetermined times, and then taken out. The presence or absence of delamination on the evaluation substrate 4 after the reflow treatment was visually observed. It was evaluated as “⊙” when occurrence of delamination was not confirmed on the evaluation substrate 4 after the reflow treatment was performed 20 times. It was evaluated as “◯” when occurrence of delamination was confirmed on the evaluation substrate 4 after the reflow treatment was performed 20 times but occurrence of delamination was not confirmed on the evaluation substrate 4 after the reflow treatment was performed 10 times. It was evaluated as “X” when occurrence of delamination was confirmed on the evaluation substrate 4 after the reflow treatment was performed 10 times but occurrence of delamination was confirmed on the evaluation substrate 4 after the reflow treatment was performed 5 times.

The results of the respective evaluations are presented in Tables 1 and 2.

TABLE 1

| | | | Example | | | |
|---|---|---|---|---|---|---|
| | | | 1 | 2 | 3 | 4 |
| Composition | Polyfunctional vinyl aromatic copolymer | | 70 | 70 | 70 | 70 |
| (parts by mass) | Curing agent | Acenaphthylene | 30 | 30 | 30 | 30 |
| | Titanate compound filler | Strontium titanate particles-1 | 30 | 60 | 65 | 100 |
| | Silica filler | Spherical silica | 90 | 60 | 55 | 20 |
| Dielectric | Cured product of resin | Relative dielectric constant | 3.6 | 4.4 | 4.5 | 6.0 |
| properties | composition | Dielectric loss tangent | 0.0012 | 0.0011 | 0.0011 | 0.0011 |
| | Fibrous base material | Glass | Q | L2 | NE | E |
| | | Relative dielectric constant | 3.5 | 4.4 | 4.5 | 6.0 |
| | | Dielectric loss tangent | 0.0015 | 0.0018 | 0.0038 | 0.0060 |
| | Difference in relative dielectric constant (cured | | 0.1 | 0 | 0 | 0 |
| | product of resin composition - fibrous base material) | | | | | |
| | Cured product of prepreg | Relative dielectric constant | 3.5 | 4.4 | 4.5 | 6.0 |
| | | Dielectric loss tangent | 0.0013 | 0.0013 | 0.0018 | 0.0024 |
| Evaluation | Skew | | ⊙ | ⊙ | ⊙ | ⊙ |
| | Coefficient of thermal expansion (ppm/° C.) | | 43 | 44 | 48 | 50 |
| | Heat resistance | | ◯ | ◯ | ◯ | ◯ |
| | | | Comparative Example | | | |
| | | | 1 | 2 | 3 | 4 |
| Composition | Polyfunctional vinyl aromatic copolymer | | 70 | 70 | 70 | 70 |
| (parts by mass) | Curing agent | Acenaphthylene | 30 | 30 | 30 | 30 |
| | Titanate compound filler | Strontium titanate particles-1 | 60 | 95 | 5 | — |
| | Silica filler | Spherical silica | — | 5 | 95 | 120 |
| Dielectric | Cured product of resin | Relative dielectric constant | 4.5 | 5.8 | 3.0 | 3.0 |
| properties | composition | Dielectric loss tangent | 0.0011 | 0.0012 | 0.0011 | 0.0012 |
| | Fibrous base material | Glass | NE | E | Q | Q |
| | | Relative dielectric constant | 4.5 | 6.0 | 3.5 | 3.5 |
| | | Dielectric loss tangent | 0.0038 | 0.0060 | 0.0015 | 0.0015 |
| | Difference in relative dielectric constant (cured | | 0 | 0.2 | 0.5 | 0.5 |
| | product of resin composition - fibrous base material) | | | | | |
| | Cured product of prepreg | Relative dielectric constant | 4.5 | 5.9 | 3.2 | 3.1 |
| | | Dielectric loss tangent | 0.0018 | 0.0026 | 0.0012 | 0.0013 |

| | | | | | |
|---|---|---|---|---|---|
| Evaluation | Skew | ⊙ | ◯ | X | X |
| | Coefficient of thermal expansion (ppm/° C.) | 62 | 58 | 43 | 40 |
| | Heat resistance | X | X | ◯ | ⊙ |

TABLE 2

| | | | Example | | | |
|---|---|---|---|---|---|---|
| | | | 3 | 5 | 6 | 7 |
| Composition | Polyfunctional vinyl aromatic copolymer | | 70 | 70 | 70 | 70 |
| (parts by mass) | Curing agent | Acenaphthylene | 30 | — | — | 30 |
| | | DVB | — | 30 | — | — |
| | | TAIC | — | — | 30 | — |
| | | Modified PPE | — | — | — | — |
| | Titanate compound filler | Strontium titanate particles-1 | 65 | 65 | 65 | — |
| | | Strontium titanate particles-2 | — | — | — | — |
| | | Calcium titanate particles | — | — | — | 55 |
| | Magnesium oxide filler | Magnesium oxide particles | — | — | — | — |
| | Silica filler | Spherical silica | 55 | 55 | 55 | 65 |
| Dielectric | Cured product of resin | Relative dielectric constant | 4.5 | 4.5 | 4.5 | 4.5 |
| properties | composition | Dielectric loss tangent | 0.0011 | 0.0011 | 0.0012 | 0.0012 |
| | Fibrous base material | Glass | NE | NE | NE | NE |
| | | Relative dielectric constant | 4.5 | 4.5 | 4.5 | 4.5 |
| | | Dielectric loss tangent | 0.0038 | 0.0038 | 0.0038 | 0.0038 |
| | Difference in relative dielectric constant (cured | | 0 | 0 | 0 | 0 |
| | product of resin composition - fibrous base material) | | | | | |
| | Cured product of prepreg | Relative dielectric constant | 4.5 | 4.5 | 4.5 | 4.5 |
| | | Dielectric loss tangent | 0.0018 | 0.0018 | 0.0019 | 0.0019 |
| Evaluation | Skew | | ⊙ | ⊙ | ⊙ | ⊙ |
| | Coefficient of thermal expansion (ppm/° C.) | | 48 | 48 | 48 | 48 |
| | Heat resistance | | ◯ | ◯ | ◯ | ◯ |
| | | | Example | | | |
| | | | 8 | 9 | 10 | 11 |
| Composition | Polyfunctional vinyl aromatic copolymer | | 70 | 50 | 70 | 50 |
| (parts by mass) | Curing agent | Acenaphthylene | 30 | 30 | 30 | 30 |
| | | DVB | — | — | — | — |
| | | TAIC | — | — | — | — |
| | | Modified PPE | — | 20 | — | 20 |
| | Titanate compound filler | Strontium titanate particles-1 | — | 65 | — | — |
| | | Strontium titanate particles-2 | 65 | — | — | — |
| | | Calcium titanate particles | — | — | — | — |
| | Magnesium oxide filler | Magnesium oxide particles | — | — | 90 | 90 |
| | Silica filler | Spherical silica | 55 | 55 | 30 | 30 |
| Dielectric | Cured product of resin | Relative dielectric constant | 4.5 | 4.5 | 3.5 | 3.5 |
| properties | composition | Dielectric loss tangent | 0.0013 | 0.0013 | 0.0011 | 0.0012 |
| | Fibrous base material | Glass | NE | NE | Q | Q |
| | | Relative dielectric constant | 4.5 | 4.5 | 3.5 | 3.5 |
| | | Dielectric loss tangent | 0.0038 | 0.0038 | 0.0015 | 0.0015 |
| | Difference in relative dielectric constant (cured | | 0 | 0 | 0 | 0 |
| | product of resin composition - fibrous base material) | | | | | |
| | Cured product of prepreg | Relative dielectric constant | 4.5 | 4.5 | 3.5 | 3.5 |
| | | Dielectric loss tangent | 0.0019 | 0.0019 | 0.0012 | 0.0013 |

| | | | | | |
|---|---|---|---|---|---|
| Evaluation | Skew | ⊙ | ⊙ | ⊙ | ⊙ |
| | Coefficient of thermal expansion (ppm/° C.) | 47 | 48 | 50 | 50 |
| | Heat resistance | ◯ | ◯ | ◯ | ◯ |

Tables 1 and 2 present the compositions of resin compositions containing the polyfunctional vinyl aromatic copolymer (A) and the curing agent (B), the fibrous base materials used in the fabrication of prepregs, and the evaluation results. As can be seen from Tables 1 and 2, when a metal-clad laminate is fabricated using the resin compositions, in cases where the resin compositions contain the high dielectric constant filler (C) and the silica filler (D) and the content ratio of the high dielectric constant filler (C) to the silica filler (D) is 10:90 to 90:10 as a mass ratio (Examples 1 to 11), the relative dielectric constant is high and the dielectric loss tangent is low, and the heat resistance is excellent and the coefficient of thermal expansion is low as compared to the other cases (Comparative Examples 1 to 4). In the case of Examples 1 to 11, it can be seen that the relative dielectric constant of a cured product of the resin composition and the relative dielectric constant of the fibrous base material can be approximated and the deterioration in signal quality due to skew can be sufficiently suppressed.

Specifically, in a case where the silica filler (D) is not contained (Comparative Example 1), the heat resistance is inferior and the coefficient of thermal expansion is high compared to Examples 1 to 11. In a case where the silica filler (D) is contained but the amount of the silica filler (D) is small so that the content ratio (mass ratio) of the high dielectric constant filler (C) to the silica filler (D) is 95:5 (Comparative Example 2) as well, the heat resistance is inferior and the coefficient of thermal expansion is high compared to Examples 1 to 11 as in Comparative Example 1. In a case where the silica filler (D) is contained but the amount of the high dielectric constant filler (C) is small so that the content ratio (mass ratio) of the high dielectric constant filler (C) to the silica filler (D) is 5:95 (Comparative Example 3), the relative dielectric constant is low compared to Examples 1 to 11. In a case where the high dielectric constant filler (C) is not contained (Comparative Example 4), the relative dielectric constant is low compared to Examples 1 to 11. In Comparative Examples 3 and 4, the relative dielectric constant of a cured product of the resin composition and the relative dielectric constant of the fibrous base material are hardly approximated and the deterioration in signal quality due to skew also cannot be sufficiently suppressed in that case.

When other curing agents (Example 5: DVB, Example 6: TAIC, Example 9: vinylbenzyl-modified polyphenylene ether) are used instead of acenaphthylene used in Examples 1 to 4 as the curing agent (B) as well, the relative dielectric constant is high, the dielectric loss tangent is low, the heat resistance is excellent, and the coefficient of thermal expansion is low. From this fact, it can be seen that the relative dielectric constant is high, the dielectric loss tangent is low, the heat resistance is excellent, and the coefficient of thermal expansion is low regardless of the kind of curing agent (B) as long as the resin compositions contain the high dielectric constant filler (C) and the silica filler (D) and the content ratio of the high dielectric constant filler (C) to the silica filler (D) is 10:90 to 90:10 as a mass ratio.

When calcium titanate particles, which are another high dielectric constant filler, are used (Example 7) instead of strontium titanate particles used in Examples 1 to 4 as the high dielectric constant filler (C) as well, and when strontium titanate particles subjected to surface treatment are used (Example 8) as well, the relative dielectric constant is high, the dielectric loss tangent is low, the heat resistance is excellent, and the coefficient of thermal expansion is low. When magnesium oxide particles, which are a magnesium oxide filler (C2), are used (Examples 10 and 11) instead of the titanate compound filler (C1) such as strontium titanate particles, calcium titanate particles, and strontium titanate particles subjected to surface treatment as the high dielectric constant filler (C) as well, the relative dielectric constant is high, the dielectric loss tangent is low, the heat resistance is excellent, and the coefficient of thermal expansion is low. From these facts, it can be seen that the relative dielectric constant is high, the dielectric loss tangent is low, the heat resistance is excellent, and the coefficient of thermal expansion is low regardless of the kind of high dielectric constant filler (C) as long as the resin compositions contain the high dielectric constant filler (C) and the silica filler (D) and the content ratio of the high dielectric constant filler (C) to the silica filler (D) is 10:90 to 90:10 as a mass ratio.

This application is based on Japanese Patent Application No. 2021-050476 filed on Mar. 24, 2021, the contents of which are included in the present application.

In order to express the present invention, the present invention has been described above appropriately and sufficiently through the embodiments. However, it should be recognized by those skilled in the art that changes and/or improvements of the above-described embodiments can be readily made. Accordingly, changes or improvements made by those skilled in the art shall be construed as being included in the scope of the claims unless otherwise the changes or improvements are at the level which departs from the scope of the appended claims.

### INDUSTRIAL APPLICABILITY

According to the present invention, there is provided a resin composition, which affords a cured product having a high relative dielectric constant, a low dielectric loss tangent, and excellent heat resistance. In addition, according to the present invention, a prepreg, a film with resin, a metal foil with resin, a metal-clad laminate, and a wiring board which are obtained using the resin composition are provided.

1. A resin composition comprising:
a polyfunctional vinyl aromatic copolymer (A) containing a repeating unit (a) derived from a divinyl aromatic compound and a repeating unit (b) derived from a monovinyl aromatic compound;
a curing agent (B);
at least one high dielectric constant filler (C) selected from the group consisting of a titanate compound filler (C1) and a magnesium oxide filler (C2); and
a silica filler (D),
wherein a content ratio of the high dielectric constant filler (C) to the silica filler (D) is 10:90 to 90:10 as a mass ratio.

2. The resin composition according to claim 1, wherein a relative dielectric constant of the titanate compound filler (C1) is 50 or more.

3. The resin composition according to claim 1, wherein the titanate compound filler (C1) includes at least one selected from the group consisting of titanium oxide particles, barium titanate particles, strontium titanate particles, calcium titanate particles, magnesium titanate particles, zinc titanate particles, lanthanum titanate particles, and neodymium titanate particles.

4. The resin composition according to claim 1, wherein the curing agent (B) includes at least one selected from the group consisting of an allyl compound, a methacrylate compound, an acrylate compound, an acenaphthylene compound, a polybutadiene compound, a polyfunctional aromatic vinyl compound, a vinyl hydrocarbon-based compound, a maleimide compound, and a polyphenylene ether compound.

5. The resin composition according to claim 1, wherein the titanate compound filler (C1) includes one of strontium titanate particles and the calcium titanate particles.

6. The resin composition according to claim 1, wherein the high dielectric constant filler (C) is subjected to surface treatment with a silane coupling agent or a titanium coupling agent.

7. The resin composition according to claim 1, wherein a content of the high dielectric constant filler (C) is 20 to 300 parts by mass with respect to 100 parts by mass of a sum of the polyfunctional vinyl aromatic copolymer (A) and the curing agent (B).

8. The resin composition according to claim 1, wherein a cured product of the resin composition has a relative dielectric constant of 3.5 to 7 at a frequency of 10 GHz and a dielectric loss tangent of 0.01 or less at a frequency of 10 GHz.

9. The resin composition according to claim 1, which is used to form an insulating layer included between wiring layers in a wiring board including 10 or more wiring layers.

10. A prepreg comprising:
the resin composition according to claim 1 or a semi-cured product of the resin composition; and
a fibrous base material.

11. The prepreg according to claim 10, wherein
a relative dielectric constant of a cured product of the prepreg is 3.5 to 7 at a frequency of 10 GHz, and
a difference between a relative dielectric constant of a cured product of the resin composition at a frequency of 10 GHz and a relative dielectric constant of the fibrous base material at a frequency of 10 GHz is 0 to 0.3.

12. The prepreg according to claim 10, wherein a relative dielectric constant of the fibrous base material is 3.5 to 7 at a frequency of 10 GHz.

13. A film with resin comprising:
a resin layer containing the resin composition according to claim 1 or a semi-cured product of the resin composition; and
a support film.

14. A metal foil with resin comprising:
a resin layer containing the resin composition according to claim 1 or a semi-cured product of the resin composition; and
a metal foil.

15. A metal-clad laminate comprising:
an insulating layer containing a cured product of the resin composition according to claim 1; and
a metal foil.

16. A wiring board comprising:
an insulating layer containing a cured product of the resin composition according to claim 1; and
wiring.

17. A metal-clad laminate comprising:
an insulating layer containing a cured product of the prepreg according to claim 10; and
a metal foil.

18. A wiring board comprising:
an insulating layer containing a cured product of the prepreg according to claim 10; and
wiring.
